(19) United States
(12) Patent Application Publication
(10) Pub. No.: US 2026/0288020 A1
(43) Pub. Date: Sep. 24, 2026

(54) STAGE APPARATUS, SUBSTRATE PROCESSING APPARATUS, ARTICLE MANUFACTURING METHOD, AND CONTROL METHOD OF STAGE APPARATUS

(71) Applicant: CANON KABUSHIKI KAISHA, Tokyo (JP)

(72) Inventors: TOSHIYUKI MYOJO, Tochigi (JP); SHIGEO KOYA, Tochigi (JP); KAZUNORI NAKAJIMA, Tokyo (JP)

(21) Appl. No.: 19/456,862

(22) Filed: Jan. 22, 2026

(30) Foreign Application Priority Data
Jan. 28, 2025 (JP) 2025-012292

(51) Int. Cl. G03F 7/00; H10P 72/76

(52) U.S. Cl. CPC G03F 7/70716; G03F 7/70525; G03F 7/707; G03F 7/70733; G03F 7/70841; G03F 7/7085; H10P 72/7612

(57) ABSTRACT

A stage apparatus includes a substrate chuck configured to support a substrate, a supplier configured to supply a gas to a space between the substrate and the substrate chuck, a pin member configured to support the substrate by protruding from a hole formed in the substrate chuck, a driver configured to relatively move the substrate chuck and the pin member, a detector configured to detect a gap between an end portion of the substrate and the substrate chuck, and a controller configured to control gas supply by the supplier based on a result of detection by the detector in an operation of separating the substrate and the substrate chuck by the driver.

### BACKGROUND

### Field of the Technology

The present disclosure relates to a stage apparatus, a substrate processing apparatus, an article manufacturing method, and a control method of the stage apparatus.

### Description of the Related Art

In a substrate processing apparatus used for a manufacturing process of a semiconductor device, a liquid crystal display device, or the like, a substrate chuck for holding (vacuum-holding) a substrate, and lift pins for separating the substrate from the substrate chuck, are used. The smoothness of holding and releasing the substrate by the substrate chuck is related not only to the productivity but also to the wear resistance of each of the substrate and the substrate chuck.

Japanese Patent Laid-Open No. 2019-83286 discloses a technique for supplying the amount of gas corresponding to the maximum capacity of a closed space that is generated when unloading a substrate from a substrate chuck due to the difficulty in separating the outer periphery of the substrate from the substrate chuck.

However, there is a problem that, even after the vacuum in the closed space is released, forcibly separating the substrate from the substrate chuck causes wear of the substrate chuck.

### SUMMARY

Embodiments of the present disclosure provide techniques advantageous in terms of wear resistance of a substrate chuck regarding cancelation of the holding of a substrate by the substrate chuck.

The present disclosure in one aspect provides a stage apparatus including a substrate chuck configured to support a substrate, a supplier configured to supply a gas to a space between the substrate and the substrate chuck, a pin member configured to support the substrate by protruding from a hole formed in the substrate chuck, a driver configured to relatively move the substrate chuck and the pin member, a detector configured to detect a gap between an end portion of the substrate and the substrate chuck, and a controller configured to control gas supply by the supplier based on a result of detection by the detector in an operation of separating the substrate and the substrate chuck by the driver.

Features of various embodiments will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a schematic view showing the configuration of a substrate processing apparatus.

FIG. 2 is a view showing the functional configuration of a controller.

FIG. 3 is a view showing an example of the configuration of a substrate stage.

FIG. 4 is a plan view showing an example of a substrate chuck.

FIG. 5 is a view for explaining a substrate transfer operation.

FIG. 6 is a view for explaining a substrate transfer operation.

FIG. 7 is a view showing an example of the drive profile of a fine moving stage.

FIGS. 8A and 8B are views each for explaining the control during a substrate transfer operation.

FIG. 9 is a view for explaining a substrate transfer operation.

FIGS. 10A and 10B are each views for explaining a method of performing gap detection based on pressure.

FIGS. 11A to 11D are each views for explaining a method of performing gap detection based on the distance between the substrate and the substrate chuck and the warpage amount of the substrate.

FIGS. 12A and 12B are views for explaining a method of performing gap detection based on the Z-direction position of the outer peripheral portion of the substrate.

FIG. 13 is a view showing an example of the temporal change of the Z deviation during a separation operation.

FIG. 14 is a view showing an example of the Z-direction moving speed during a separation operation.

FIG. 15 is a view for explaining an example of the gas supply control.

FIGS. 16A to 16C are views each for explaining an example of the gas supply control.

FIG. 17 is a view for explaining an example of the arrangement of a pressure sensor.

FIGS. 18A and 18B are views each for explaining an example of the gas supply control.

FIG. 19 is a view for explaining an example of the gas supply control in a case where the substrate warps.

FIG. 20 is a view for explaining an example of the gas supply control in a case where the substrate warps.

FIGS. 21A and 21B are views each for explaining the control during a substrate transfer operation.

FIG. 22 is a view for explaining a substrate transfer operation.

FIG. 23 is a view showing an example of the configuration of a substrate stage.

FIG. 24 is a plan view showing an example of a substrate chuck.

FIGS. 25A to 25C are views each for explaining an example of the gas supply control.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

In the embodiments, a substrate processing apparatus that processes a substrate can include a lithography apparatus, a measurement apparatus, an inspection apparatus, and the like. The lithography apparatus is an apparatus configured to form a pattern on a substrate, and includes, for example, an exposure apparatus, an imprint apparatus, a planarization apparatus, a rendering apparatus, and the like. The exposure apparatus includes an apparatus that projects the pattern of an original (mask or reticle) to a substrate and exposes the substrate. The imprint apparatus includes an apparatus that molds an imprint material on a substrate with a mold and forms the pattern of the imprint material on the substrate. The planarization apparatus includes an apparatus that planarizes a composition on a substrate using a mold having a flat surface. The rendering apparatus includes an apparatus that renders a pattern on a substrate using a charged particle beam (electron beam, ion beam, or the like). The measurement apparatus is an apparatus configured to measure a substrate, and includes, for example, an alignment measurement apparatus used to align an original and a substrate. The inspection apparatus is an apparatus configured to inspect a substrate, and includes, for example, an overlay inspection apparatus that inspects the overlay precision of a pattern formed on a substrate.

### First Embodiment

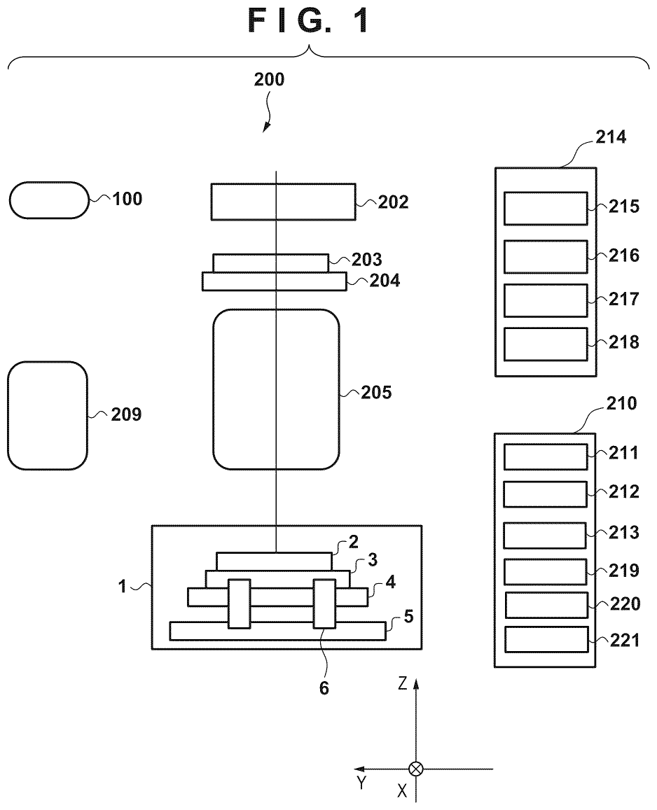

FIG. 1 is a schematic view showing the configuration of an exposure apparatus 200 as a substrate processing apparatus according to the first embodiment. The exposure apparatus 200 is used for a lithography process that is a manufacturing process of a device such as a semiconductor device or a liquid crystal display device. The exposure apparatus 200 is a lithography apparatus that exposes a substrate using an original to transfer the pattern of the original to the substrate, that is, form the pattern on the substrate.

In this specification and the accompanying drawings, directions are indicated in an XYZ coordinate system in which a direction parallel to a plane on which a substrate is arranged is defined as an X-Y plane. Directions parallel to the X-axis, Y-axis, and Z-axis in the XYZ coordinate system are defined as the X direction, the Y direction, and the Z direction, respectively. A rotation about the X-axis, a rotation about the Y-axis, and a rotation about the Z-axis are defined as θX, θY, and θZ, respectively.

As shown in FIG. 1, the exposure apparatus 200 includes a substrate stage 1 (stage apparatus), a controller 100, an illumination optical system 202, an original stage 204, a projection optical system 205, an off-axis scope 209, a substrate conveyance system 210, and an original conveyance system 214.

In the exposure apparatus 200, the illumination optical system 202 illuminates an original 203 with light (exposure light) from a light source. The projection optical system 205 has a function of imaging light traveling from an object plane onto an image plane. The projection optical system 205 projects, on a substrate 2, the light having passed through (the pattern of) the original 203, and forms the image of the pattern of the original 203 on the substrate.

The original stage 204 holds the original 203 via an original chuck (not shown) configured to suck and hold the original 203. The original stage 204 is a stage that linearly moves in the X, Y, and Z directions and is driven to rotate in the θX, θY, and θZ directions. The original stage 204 can independently control driving in each direction. The exposure apparatus 200 includes a laser interferometer (not shown) to measure the position of the original stage 204 at high precision. The position of the original stage 204 is decided from the displacement amount of the original stage 204 that is measured by the laser interferometer.

The original conveyance system 214 includes a hand 215, a pre-alignment stage 216, a conveyance robot 217, and a storage 218. The conveyance robot 217 is constituted by an articulated robot. The conveyance robot 217 includes an original holder that holds the original 203 and can drive the original holder to an arbitrary position in the XYZ space. The storage 218 includes a table on which the original 203 is placed and stores the original 203 conveyed from outside the apparatus. The original 203 stored in the storage 218 is conveyed to the pre-alignment stage 216 by the conveyance robot 217.

In the pre-alignment stage 216, the mark of the original 203 is detected (observed) by a microscope to measure a positional relationship (misalignment of the original 203 with respect to the pre-alignment stage 216) between the original 203 and the pre-alignment stage 216. After the positional relationship between the original 203 and the pre-alignment stage 216 is measured, the hand 215 holds the original 203 on the pre-alignment stage and drives the original 203 along a guide to a position (original supply position) where the original 203 is handed over to the original stage 204. At the original supply position, the hand 215 hands over the original 203 to the original stage 204. The original stage 204 vacuum-sucks and holds the original 203 via the original chuck. Misalignments of the original 203 with respect to the pre-alignment stage 216 in the X, Y, and θZ directions can be corrected by adjusting the position where the original stage 204 receives the original 203.

The substrate conveyance system 210 includes a supply hand 211, a recovery hand 212, a storage 213, a pre-alignment unit 219, a conveyance robot 220, and a temporary table 221. The storage 213 stores the substrate 2. The conveyance robot 220 is constituted by an articulated robot. The conveyance robot 220 includes a substrate holder that holds the substrate 2 and can drive the substrate holder to an arbitrary position in the XYZ space. The conveyance robot 220 picks up the substrate 2 from the storage 213 and places the substrate 2 in the pre-alignment unit 219. In the pre-alignment unit 219, the outer peripheral portion of the substrate 2 is irradiated with light, and the reflected light is detected by a sensor to measure the position of the outer shape of the substrate 2 with respect to the pre-alignment unit 219.

The supply hand 211 is a mechanism configured to transfer the substrate 2 from the pre-alignment unit 219 to the substrate stage 1 (pin members 6 provided on a coarse moving stage 5). The supply hand 211 can vacuum-suck and hold the substrate 2. The recovery hand 212 is a mechanism configured to transfer the substrate 2 from the substrate stage 1 to the temporary table 221. The recovery hand 212 can vacuum-suck and hold the substrate 2. The temporary table 221 is a table configured to temporarily place the substrate 2 recovered from the substrate stage 1 by the recovery hand 212. The conveyance robot 220 cannot directly receive the substrate 2 from the recovery hand 212, and thus the conveyance robot 220 transfers the substrate 2 via the temporary table 221.

The substrate stage 1 includes a fine moving stage 4 and the coarse moving stage 5. The substrate stage 1 vacuum-sucks and holds the substrate 2 via a substrate chuck 3 placed on the fine moving stage 4 and supporting the substrate 2. The fine moving stage 4 is a stage that includes a driver (actuator) for causing the stage to linearly move in the X, Y, and Z directions and be driven to rotate in the θX, θY, and θZ directions. The fine moving stage 4 can independently control driving in each direction. The exposure apparatus 200 includes a laser interferometer (not shown) to measure the position of the fine moving stage 4 at high precision. The position of the fine moving stage 4 is decided from the displacement amount of the fine moving stage 4 that is measured by the laser interferometer.

The pin member 6 is used when receiving the substrate 2 from the supply hand 211 and when transferring the substrate 2 to the recovery hand 212. The pin member 6 can vacuum-suck and hold the substrate 2. In this embodiment, at least three pin members 6 are fixed to the coarse moving stage 5 and provided to stand with respect to a holding surface of the substrate chuck 3 on which the substrate 2 is held. The pin members 6 are fixed to the coarse moving stage 5 and thus driven together with the coarse moving stage 5. Note that three pin members 6 are provided in this embodiment, but the number of pin members 6 is not limited to any specific number as long as they can satisfactorily and stably hold the substrate 2 in accordance with the size, material, and mass of the substrate 2.

The coarse moving stage 5 is a stage that linearly moves in the X and Y directions and is driven to rotate in the θZ direction. The coarse moving stage 5 is controlled to follow the position of the fine moving stage 4 via an actuator, such as a linear motor, based on a distance between the coarse moving stage 5 and the fine moving stage 4 that is measured by, for example, a capacitance sensor.

In an outer space (outer space of the substrate chuck 3) as a space around the substrate stage 1, a temperature-controlled gas is supplied from a gas supply port (not shown) provided in the exposure apparatus 200, and the ambient temperature, humidity, and the like of the substrate stage 1 are maintained at predetermined values. Hereinafter, the outer space of the substrate stage 1 in which the ambient temperature, humidity, and the like of the substrate stage 1 are maintained at predetermined values will be sometimes called a stage space.

The off-axis scope 209 measures the position of the substrate 2 by detecting a mark (alignment mark) provided on the substrate 2 held by the substrate stage 1.

The controller 100 is constituted by an information processing apparatus (computer) including a CPU, a memory, and the like. The controller 100 comprehensively controls the respective units of the exposure apparatus 200 to operate the exposure apparatus 200 in accordance with programs stored in a storage unit. The controller 100 controls, for example, a sequence (exposure sequence) regarding exposure processing of exposing the substrate 2, a sequence (supply sequence) of supplying the substrate 2 to the substrate stage 1, a sequence (recovery sequence) of recovering the substrate 2 from the substrate stage 1, and the like.

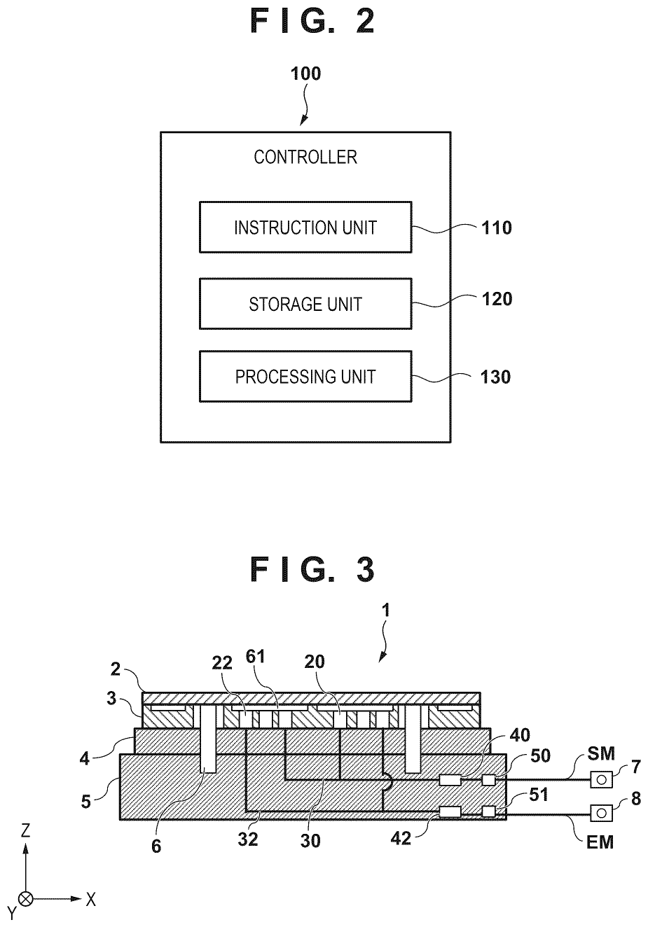

FIG. 2 shows the functional configuration of the controller 100. The controller 100 can include an instruction unit 110, a storage unit 120, and a processing unit 130. The instruction unit 110 instructs the control amounts to respective drivers including the fine moving stage 4. The storage unit 120 stores various data and programs related to exposure control. The processing unit 130 executes various processes related to exposure control. For example, the processing unit 130 calculates the drive target positions of the substrate stage 1 and the original stage 204. Furthermore, the processing unit 130 executes an exposure sequence and a substrate supply and recovery sequence in accordance with the control program stored in the storage unit 120.

With reference FIG. 3, a method of vacuum-sucking and holding the substrate 2 by the substrate chuck 3, and a method of supplying a gas to the space between the substrate 2 and the substrate chuck 3, will be explained. FIG. 3 is a schematic view showing an example of the configuration of the substrate stage 1. Note that the space between the substrate 2 and the substrate chuck 3 will sometimes be called a space 61 hereinafter. As shown in FIG. 3, the substrate stage 1 includes an exhaust mechanism EM used when holding the substrate 2 by the substrate chuck 3 and includes a supply mechanism SM used when canceling the holding of the substrate 2 by the substrate chuck 3.

The exhaust mechanism EM is a mechanism configured to exhaust a gas from the space 61 (first space) serving as the space between the substrate 2 and the substrate chuck 3. The exhaust mechanism EM includes a flow path (pipe) 32 (third flow path), a solenoid valve 42 (second valve), and a regulator 51. The supply mechanism SM is a mechanism configured to supply a gas to the space 61. The supply mechanism SM includes a flow path (pipe) 30 (first flow path), a solenoid valve 40 (first valve), and a regulator 50.

The substrate stage 1 vacuum-sucks and holds the substrate 2 by the substrate chuck 3 by exhausting the gas from the space 61 (decompression space) serving as the space between the substrate 2 and the substrate chuck 3 and reducing the pressure by the exhaust mechanism EM. The flow paths 30 and 32 are connected to the substrate chuck 3. The substrate chuck 3 is vacuum-sucked and held on the fine moving stage 4. The fine moving stage 4 is placed on the coarse moving stage 5. In this embodiment, the solenoid valves 40 and 42 and the regulators 50 and 51 are assembled in the coarse moving stage 5.

The flow path 30 connects, via the solenoid valve 40 provided on the flow path 30, the space 61 and a positive-pressure tank 7 serving as a positive-pressure source (gas supply source) that generates a positive pressure. The positive-pressure tank 7 is provided outside the coarse moving stage 5 and constituted as, for example, a plant facility. The solenoid valve 40 is interposed between the positive-pressure tank 7 and the substrate chuck 3. The flow path 32 connects, via the solenoid valve 42 provided on the flow path 32, the space 61 serving as the space between the substrate 2 and the substrate chuck 3, and a vacuum pump 8 that generates a negative pressure.

The regulator 51 is interposed between the vacuum pump 8 and the substrate chuck 3, specifically, between the vacuum pump 8 and the solenoid valve 42, and can regulate the pressure of the space 61 to a desired vacuum pressure. To supply the pressure regulated by the regulator 51 to the substrate chuck 3, the solenoid valve 42 is arranged on the side of the substrate chuck 3 with respect to the regulator 51. Under the control of the controller 100, the solenoid valve 42 is turned on (that is, the solenoid valve 42 is opened) to regulate the pressure of the space 61 by the vacuum pump 8. Also, under the control of the controller 100, the solenoid valve 42 is turned off (that is, the solenoid valve 42 is closed) to cancel the regulation of the pressure of the space 61 by the vacuum pump 8.

The regulator 50 is interposed between the positive-pressure tank 7 and the substrate chuck 3, specifically, between the positive-pressure tank 7 and the solenoid valve 40, and can regulate the pressure of the gas supplied from the positive-pressure tank 7 to a desired pressure. Regulating the pressure of the gas supplied from the positive-pressure tank 7 also means regulating the flow rate of the gas supplied from the positive-pressure tank 7. To supply the pressure regulated by the regulator 50 to the substrate chuck 3, the solenoid valve 40 is arranged on the side of the substrate chuck 3 with respect to the regulator 50. Under the control of the controller 100, the solenoid valve 40 is turned on (that is, the solenoid valve 40 is opened) to regulate the pressure of the space 61 by the positive-pressure tank 7. Also, under the control of the controller 100, the solenoid valve 40 is turned off (that is, the solenoid valve 40 is closed) to cancel the regulation of the pressure of the space 61 by the positive-pressure tank 7.

The solenoid valves 40 and 42 may be replaced with servo valves capable of freely setting the opening/closing degree, proportional solenoid valves controllable in proportion to the current, or the like.

When holding the substrate 2 by the substrate chuck 3, the solenoid valve 42 is turned on to depressurize the space 61 by the vacuum pump 8 and vacuum-suck the substrate 2 by the substrate chuck 3.

When canceling the holding of the substrate 2 by the substrate chuck 3, the solenoid valve 42 is turned off and the solenoid valve 40 is turned on to supply the gas from the stage space and the positive-pressure tank 7 to the space 61.

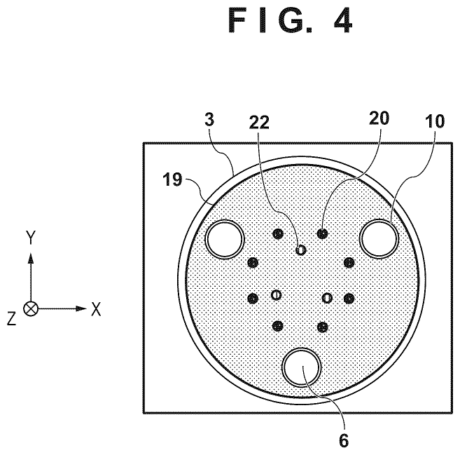

FIG. 4 is a plan view of the substrate chuck 3 when viewed from the +Z direction. In FIG. 4, an annular sealing portion 19 is provided on the substrate chuck 3 along the outer periphery of the substrate chuck 3, but the sealing portion 19 provided on the substrate chuck 3 is not always necessary. The number and layout of sealing portions 19 provided on the substrate chuck 3 are not limited to any specific number and any specific layout.

A plurality of projections (not shown) called chuck pins are provided on the substrate chuck 3, and the chuck pins define a holding surface on which the substrate 2 is held. A supply hole 20 continuous with the flow path 30 and an exhaust hole 22 continuous with the flow path 32 are formed in the holding surface of the substrate chuck 3.

In the example shown in FIG. 4, eight supply holes 20 are provided at equal intervals on the same circle (concentrically) on which distances from the center of the substrate chuck 3 are equal. However, the present disclosure is not limited to this. Also, three exhaust holes 22 are provided on the same circle (concentrically) on which distances from the center of the substrate chuck 3 are equal. However, the present disclosure is not limited to this.

As shown in FIG. 4, through holes 10 are provided in the substrate chuck 3 and the fine moving stage 4 so that the pin members 6 pass through the through holes 10. The fine moving stage 4 can be driven in the Z direction without interfering with the pin members 6.

The operation of vacuum-sucking and holding the substrate 2 by the substrate chuck 3 is performed by exhausting, by the exhaust mechanism EM via the exhaust holes 22, the gas in the space 61 serving as the space between the substrate 2 and the substrate chuck 3. In this manner, the gaps between the substrate 2 and the small chuck pins are evacuated via the exhaust holes 22, and the substrate chuck 3 can vacuum-suck and hold the substrate 2 by a uniform force. In this embodiment, the presence of the sealing portion 19 between the substrate 2 and the substrate chuck 3 can prevent the inflow of the gas (air) from the stage space and enable vacuum-sucking the substrate 2.

The operation of canceling the holding of the substrate 2 by the substrate chuck 3 is performed by supplying, by the supply mechanism SM (supplier) via the supply holes 20, the gas from the positive-pressure tank 7 to the space 61.

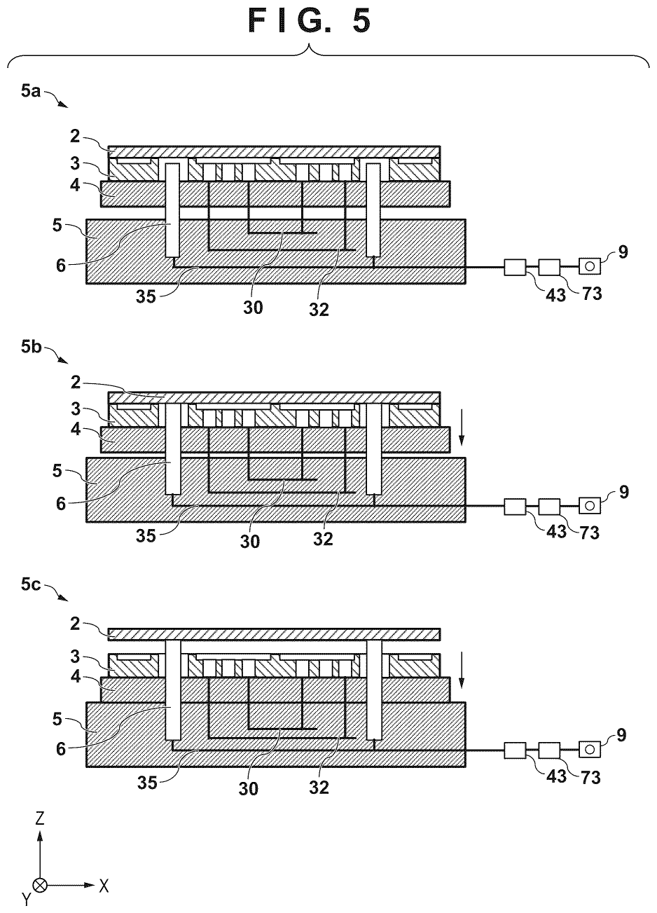

Next, a method of transferring the substrate 2 from the substrate chuck 3 to the pin members 6 will be explained with reference to FIG. 5. FIG. 5 shows sectional views of the substrate stage 1 in states 5a, 5b, and 5c, respectively.

The pin member 6 is a member that protrudes from the through hole 10 formed in the substrate chuck 3, thereby supporting the substrate 2. The fine moving stage 4 can include a driver that drives the fine moving stage 4 in the Z direction along the pin members 6 (in the longitudinal direction thereof) so as to change the height of the fine moving stage 4. Note that the driver of the fine moving stage 4 can cause the fine moving stage 4 to be driven while tilted in the Z direction in accordance with the positions of the three pin members 6 in the Z direction. As described above, the pin members 6 are fixed to the coarse moving stage 5 drivable in the X and Y directions. The position of the pin member 6 is measured by a measurement device including, for example, an interferometer, a capacitance sensor, an encoder, and the like.

The pin members 6 are connected to a vacuum pump 9 via a flow path 35. A regulator 73 and a solenoid valve 43 are interposed between the vacuum pump 9 and the pin members 6. To supply a pressure regulated by the regulator 73 to the pin members 6, the solenoid valve 43 is arranged on the side of the pin members 6 with respect to the regulator 51. Under the control of the controller 100, the solenoid valve 43 is turned on (that is, the solenoid valve 43 is opened) to regulate the pressure of the space between the substrate 2 and the substrate chuck 3 by the vacuum pump 9 via the pin members 6. Also, under the control of the controller 100, the solenoid valve 43 is turned off (that is, the solenoid valve 43 is closed) to cancel the regulation of the pressure of the space between the substrate 2 and the substrate chuck 3 by the vacuum pump 9 via the pin members 6. In this embodiment, the solenoid valve 43 and the regulator 73 are provided outside the coarse moving stage 5, that is, in the stage space, but may be assembled in the coarse moving stage 5. The vacuum pump 9 is constituted as, for example, a plant facility.

In the state 5a shown in FIG. 5, the fine moving stage 4 is positioned in the +Z direction, and the substrate chuck 3 vacuum-chucks the substrate 2. In the state 5b shown in FIG. 5, as indicated by an arrow, the fine moving stage 4 is driven in the −Z direction to bring the pin members 6 and the substrate 2 into contact with each other. At this time, the fine moving stage 4 may stop the driving. After the pin members 6 and the substrate 2 contact each other, the holding of the substrate 2 by the substrate chuck 3 is canceled. In addition, the solenoid valve 43 is turned on to vacuum-suck and hold the substrate 2 by the pin members 6. In the state in which the pin members 6 hold the substrate 2, the fine moving stage 4 is further driven in the −Z direction to transfer the substrate 2 from the substrate chuck 3 to the pin members 6, as illustrated in the state 5c shown in FIG. 5.

Here, the method of driving the fine moving stage 4 to transfer the substrate 2 from the substrate chuck 3 to the pin members 6 has been explained. However, the present disclosure is not limited to this, and it is only necessary to change the relative positions of the substrate chuck 3 and pin members 6 in the Z direction. For example, a driver may drive the whole pin members 6 or their distal ends in the Z direction to transfer the substrate 2 from the substrate chuck 3 to the pin members 6. Changing the relative positions of the substrate chuck 3 and pin members 6 is synonymous with relatively driving the substrate chuck 3 and the pin members 6.

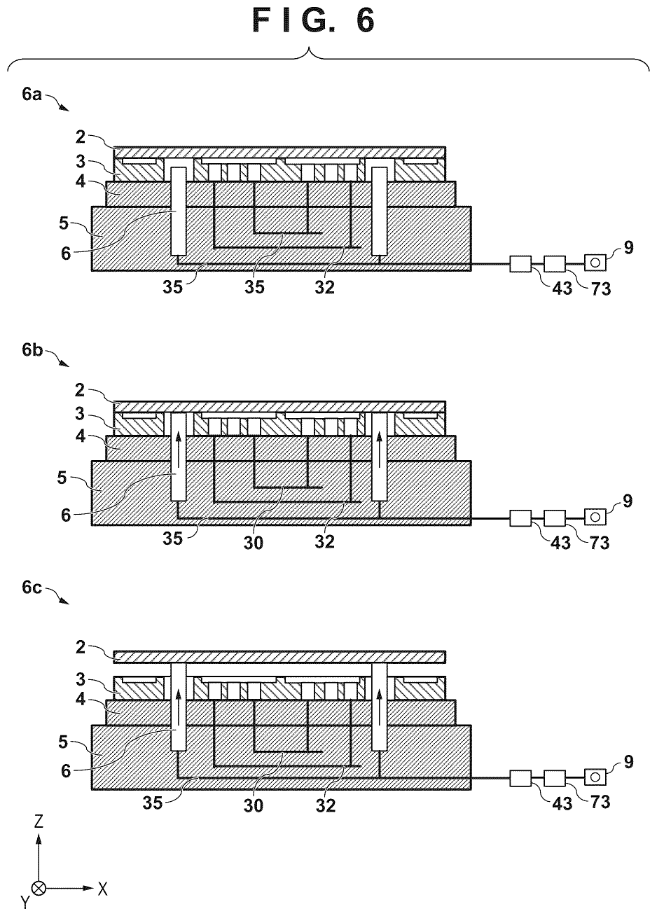

A method of transferring the substrate 2 from the substrate chuck 3 to the pin members 6 by driving the whole pin members 6 in the Z direction will be explained with reference to FIG. 6. FIG. 6 shows sectional views of the substrate stage 1 in states 6a, 6b, and 6c, respectively. A driver that drives the pin members 6 may be incorporated in the pin members 6, or provided outside the pin members 6 and connected to the pin members 6. Note that, as described above, the distal ends of the pin members 6 may be driven (extended) in the Z direction to transfer the substrate 2 from the substrate chuck 3 to the pin members 6, instead of driving the whole pin members 6.

In the state 6a shown in FIG. 6, the pin members 6 are positioned in the −Z direction and do not contact the substrate 2. In this state, the substrate chuck 3 holds the substrate 2. In the state 6b shown in FIG. 6, as indicated by an arrow, driving the pin member 6 in the +Z direction causes the pin member 6 to approach and come into contact with the substrate 2. After the pin members 6 and the substrate 2 contact each other, the driving of the pin members 6 is stopped, and the holding of the substrate 2 by the substrate chuck 3 is canceled. Then, the solenoid valve 43 is turned on to vacuum-suck the substrate 2 by the pin members 6. In the state in which the pin members 6 hold the substrate 2, the pin members 6 are further driven in the +Z direction to transfer the substrate 2 from the substrate chuck 3 to the pin members 6, as illustrated in the state 6c shown in FIG. 6.

The substrate stage 1 (stage apparatus) can include the driver that drives the fine moving stage 4 shown in FIG. 5, the driver that drives the pin member 6 shown in FIG. 6, or both of them. These drivers function as a driver (relative driver) that moves at least one of the substrate chuck 3 and the pin members 6 in a direction in which the pin members 6 rise and lower through the through holes 10 relative to the height of the holding surface of the substrate chuck 3.

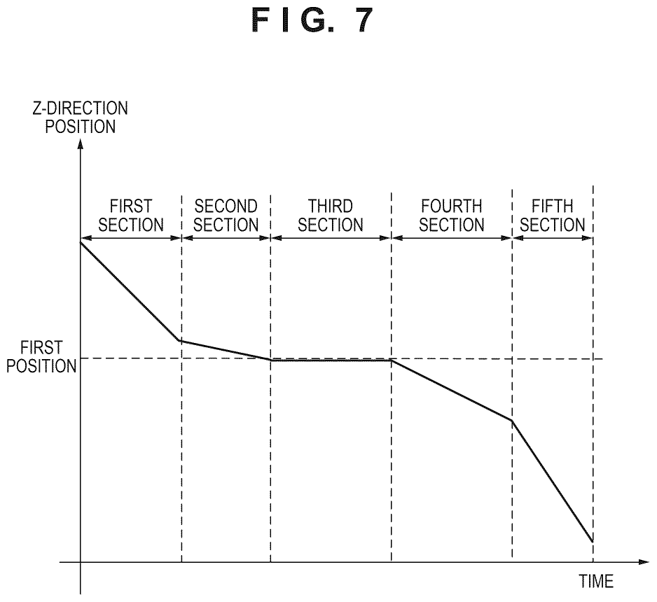

The controller 100 controls the driver, the supply mechanism SM, and the exhaust mechanism EM by following a control sequence based on a control profile (drive profile) defining the time-series transition of the target position of the fine moving stage 4 serving as the driver. FIG. 7 shows an example of the control profile (drive profile) defining the time-series transition of the target position of the fine moving stage 4 serving as the driver. The target position of the driver indicates the target position concerning the relative position between the substrate chuck 3 and the pin member 6. FIG. 7 shows the relationship between time and the Z-direction position of the fine moving stage 4 in the operation of transferring the substrate 2 from the substrate chuck 3 to the pin members 6. Note that the change amount of the Z-direction position of the fine moving stage 4 is synonymous with the change amount of the Z-direction position of the substrate chuck 3.

In the first section, the instruction unit 110 instructs the fine moving stage 4 to set the first position stored in the storage unit 120 as the target position to move the fine moving stage 4 at high speed in the −Z direction. When driving the fine moving stage 4 in the −Z direction, the first position is set to be the same position as the Z-direction position of the fine moving stage 4 where the pin members 6 come into contact with the substrate 2, or the position on the +Z direction side of this position. Here, the example is shown in which the fine moving stage 4 moves in the −Z direction as in FIG. 5. However, since the case where the pin members 6 are moved in the +Z direction as in FIG. 6 is different from this example only in the moving direction, FIG. 7 is applicable to the case by exchanging the −Z direction and the +Z direction in FIG. 7. The drawings and explanations described below can also be applied to the case where the pin members 6 are moved in the +Z direction by exchanging the −Z direction and the +Z direction. Furthermore, in a form where both the fine moving stage 4 and the pin members 6 are driven, moving the fine moving stage 4 in the Z direction in the explanation of FIG. 7 and the drawings described below may be replaced with an explanation of relatively moving the fine moving stage 4 and the pin members 6.

In the second section, the controller 100 moves the fine moving stage 4 at low speed in the −Z direction, and monitors the drive current value in the driving of the fine moving stage 4. By monitoring the drive current value while moving the fine moving stage 4 in the −Z direction, the controller 100 can detect the drive current value which changes when the pin members 6 come into contact with the substrate 2, thereby detecting that the pin members 6 have come into contact with the substrate 2. The reason why the fine moving stage 4 is driven at low speed in the second section is that the substrate 2 and the pin members 6 may be damaged if the substrate 2 is brought into contact with the pin members 6 at high speed. If it is detected that the pin members 6 have come into contact with the substrate 2 by monitoring the drive current value, the controller 100 stops moving the fine moving stage 4 in the −Z direction, and ends the second section. Note that the controller 100 may update the value of the first position stored in the storage unit 120 with the value of the Z-direction position of the fine moving stage 4 at the time of detection of the contact between the pin members 6 and the substrate 2 in the second section. By updating the first position in this manner, the time required for the second section can be reduced.

If the coordinates of the fine moving stage 4 when the substrate 2 comes into contact with the pin members 6 are the same as those of the first position, the substrate 2 and the pin members 6 are in contact with each other when the fine moving stage 4 has m oved at the first position. In this case, at the same time as the start of the second section, it is detected that the substrate 2 and the pin members 6 have come into contact from the drive current value. Hence, the fine moving stage 4 is not moved at low speed in the second section, and the operation transitions to the third section. Note that if it is known that the coordinates of the fine moving stage 4 when the substrate 2 and the pin members 6 come into contact are the same as those of the first position, the second section may be omitted and the operation may transition to the third section after the first section. If the substrate 2 and the pin members 6 are in contact, both may wear or be damaged in the third section due to vibration of the apparatus or the like. To prevent this, the operation may transition to the third section after moving the pin members 6 and the substrate 2 only by a small distance in the separation direction within the range where the substrate 2 can be chucked by sucking the gas by the pin members 6. The separation distance is, for example, 10 to 70 μm. Also, by updating the first position at a position where the substrate 2 and the pin members 6 are separated by a small distance, and defining the position where the substrate 2 and the pin members 6 are separated by the small distance as the position where the first section ends, the second section may be omitted.

In the third section, the controller 100 stops suction of the gas between the substrate 2 and the substrate chuck 3, and in parallel therewith, supplies a gas between the substrate 2 and the substrate chuck 3. In the third section, the pin members 6 also start to suck the gas between the substrate 2 and the pin members 6.

In the fourth section, the controller 100 moves the fine moving stage 4 at low speed in the −Z direction, thereby separating the substrate 2 and the substrate chuck 3 by a small distance.

In the fifth section, the fine moving stage 4 is moved at high speed in the −Z direction to the final position in the Z direction.

In the example shown in FIG. 7, the separation process between the substrate 2 and the substrate chuck 3 is divided into two sections of the fourth section and the fifth section. However, the present disclosure is not limited to this, and the separation process may be divided into three or more sections. For example, the separation process between the substrate 2 and the substrate chuck 3 may be divided into three sections of the fourth to sixth sections, and the fine moving stage 4 may be moved at low speed in the fourth section, at middle speed in the fifth section, and at high speed in the sixth section. In addition, in this embodiment, the speed is changed at the instant of transition from the previous section to the next section. However, the present disclosure is not limited to this, and the speed may be gradually changed between the previous section and the next section.

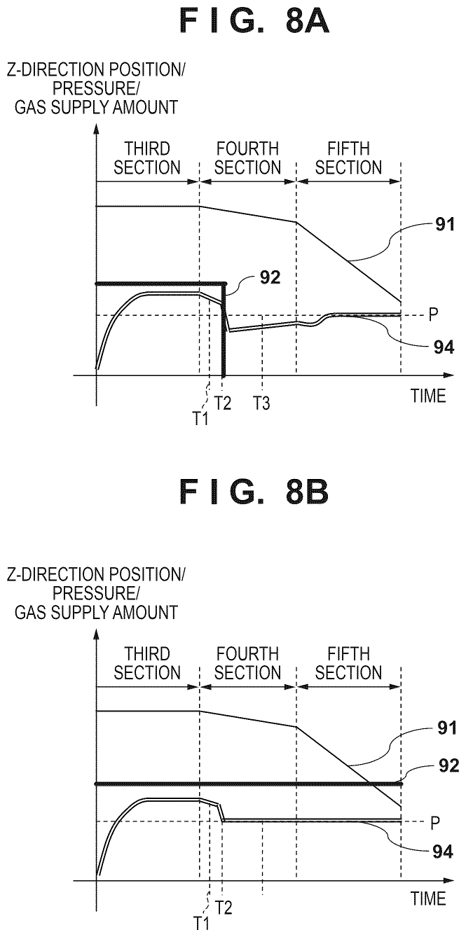

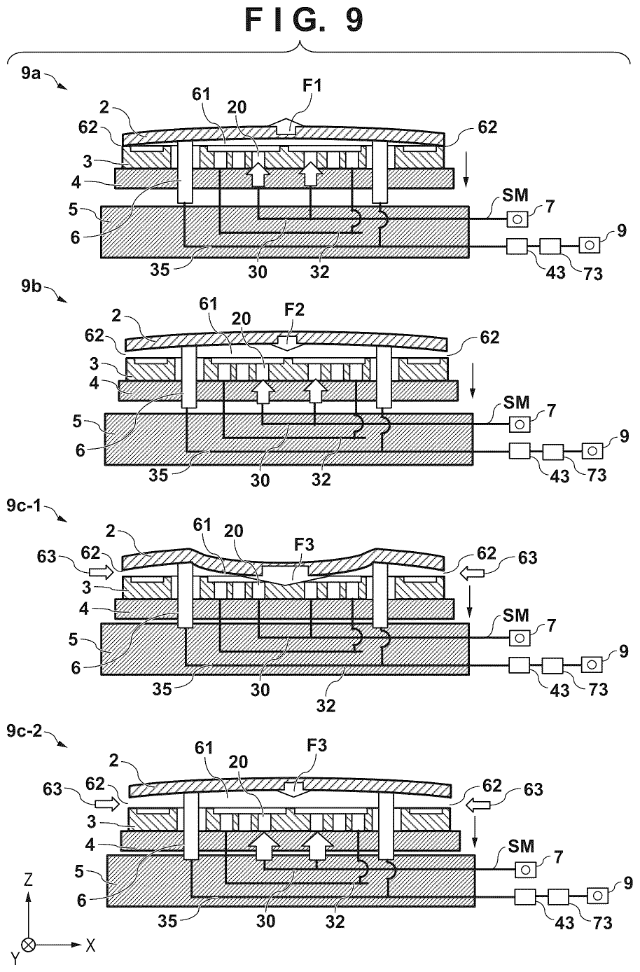

With reference to FIGS. 8A to 9, an embodiment will be explained in which the substrate 2 is separated from the substrate chuck 3 while suppressing wear of the substrate chuck 3. FIG. 8A shows the change of a Z-direction position 91, the change of a gas supply amount 92, and the change of a pressure 94 of the space 61 between the substrate 2 and the substrate chuck 3 from the middle of the third section to the fifth section shown in FIG. 7 according to a conventional technique. P represents atmospheric pressure. In FIG. 8A, T1 indicates an early timing in the fourth section. The state of the fine moving stage 4 at this timing is shown as a state 9a in FIG. 9. Here, since a pressurized gas is supplied from the supply mechanism SM, the pressure of the space 61 becomes equal to or above atmospheric pressure. This pressure generates, on the substrate 2, a force F1 in a direction of separating from the substrate chuck 3. Therefore, chucking by a negative pressure does not occur between the substrate 2 and the substrate chuck 3.

In FIG. 8A, T2 indicates a timing when the pressure of the space 61 becomes equal to atmospheric pressure. The state of the fine moving stage 4 at this timing is shown as a state 9b in FIG. 9. Here, since the fine moving stage 4 is moved in the −Z direction, a gap 62 is formed between the end portion (outer peripheral portion) of the substrate 2 and the substrate chuck 3, and this releases the pressure. Accordingly, the pressure of the space 61 becomes equal to atmospheric pressure. Therefore, a force F2 corresponding to the weight of the substrate 2 is generated on the substrate 2 in a direction of approaching the substrate chuck 3. Thus, at this point of time, chucking by a negative pressure does not occur between the substrate 2 and the substrate chuck 3. Hence, at this point of time, the gas supply from the supply mechanism SM is stopped.

However, after this, re-chucking between the substrate 2 and the substrate chuck 3 occurs. The reason for this will be explained below. In FIG. 8A, T3 indicates a timing when the fine moving stage 4 has further moved in the −Z direction from the position at T2. The state of the fine moving stage 4 at this timing is shown as a state 9c-1 in FIG. 9. Here, since the distance between the substrate 2 and the substrate chuck 3 increases, the space 61 expands, and a negative pressure generated due to the expansion causes the gas around the substrate chuck 3 to be supplied through the gap 62. If a supply amount of the gas 63 is equal to the expansion amount, the negative pressure is eliminated and the space 61 becomes equal to atmospheric pressure. However, if the gap 62 is narrow or the −Z moving speed is high, the supply amount per unit time is insufficient with respect to the expansion amount of the space 61 per unit time due to a pressure loss, thereby leaving a negative pressure between the substrate 2 and the substrate chuck 3. Therefore, a force F3, which corresponds to the sum of the weight of the substrate 2 and the chucking force by the negative pressure, is generated on the substrate 2 in the direction approaching the substrate chuck 3. Due to the force F3, the substrate 2 adheres to the substrate chuck 3 again. When separating the substrate 2 adhering to the substrate chuck 3 again, the substrate chuck 3 wears. In FIG. 8A, the pressure 94 indicates that the negative pressure continues from the fourth section to the middle of the fifth section.

As a countermeasure, in this embodiment, the pressurized gas is supplied from the supply mechanism SM even after T2. FIG. 8B shows the Z-direction position 91, the gas supply amount 92, and the pressure 94 between the substrate 2 and the substrate chuck 3 in this case. The state of the fine moving stage 4 at T3 in FIG. 8B is shown as a state 9c-2 in FIG. 9. Due to the gas supply from the supply mechanism SM, the gas supply amount per unit time increases. This eliminates the insufficient gas supply with respect to the expansion amount of the space 61 per unit time, thereby reducing the force F2 generated in the direction of the substrate 2 approaching the substrate chuck 3. That is, the chucking force between the substrate 2 and the substrate chuck 3 decreases, and wear of the substrate chuck 3 can be significantly reduced. Furthermore, even if the −Z moving speed is increased, wear of the substrate chuck 3 is less likely to occur. Accordingly, it is also possible to shorten the unload time by increasing the −Z moving speed.

So far, it has been explained that since the chucking force between the substrate 2 and the substrate chuck 3 is generated even after the gap 62 is formed, it is necessary to supply a gas even after the gap 62 is formed. Here, the factor that generates the chucking force between the substrate 2 and the substrate chuck 3 changes before and after the gap 62 is formed, so that the chucking force to be generated can also change. For example, before the gap 62 is formed, the adhesion force generated by the surface roughness of the substrate 2 and the substrate chuck 3 is added to the chucking force. However, after the gap 62 is formed, the influence of the adhesion rapidly decreases. Instead, the chucking force can increase due to insufficient supply of gas from around the substrate chuck 3. Therefore, a gap detection means (detector) for detecting the gap 62 may be provided, and gas supply may be controlled based on a detection result thereof. The gap detection means will be explained below. Although various gas detection methods will be presented below, one of these may be employed, or a combination of some of these may be employed.

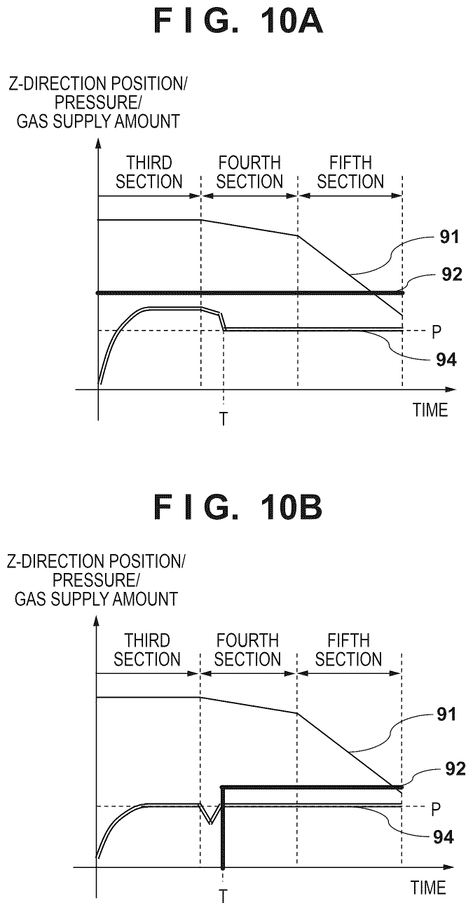

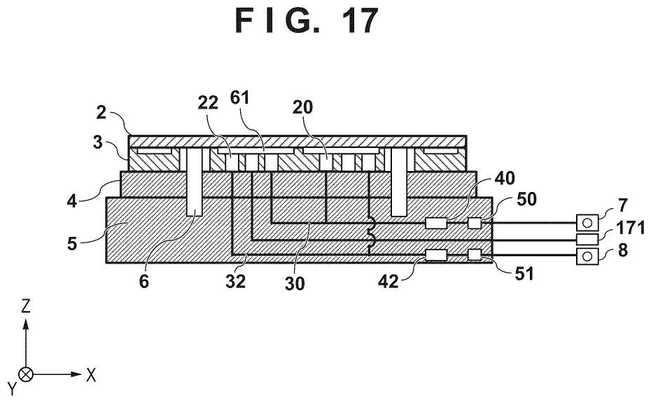

A form of performing gap detection by pressure will be explained. If the gap 62 is formed between the end portion of the substrate 2 and the substrate chuck 3, a gas 63 around the substrate chuck 3 enters the space 61 so that the pressure of the space 61 approaches the pressure around the substrate chuck 3. Hence, the time when the gap 62 is formed can be detected from the change of the pressure of the space 61. FIG. 17 shows an example of the configuration in which a pressure sensor 10 is installed in a system communicating with the space 61 to measure the pressure of the space 61 in the substrate stage 1. In FIG. 17, the pressure sensor 10 is provided outside the substrate stage 1. However, the present disclosure is not limited to this, and the pressure sensor 10 may be provided inside the substrate stage 1. FIG. 10A shows an example of the change of the Z-direction position 91, the change of the gas supply amount 92, and the change of the pressure 94 of the space 61 from the third section to the fifth section in a case in which a pressurized gas is supplied in the third section where the fine moving stage 4 is stopped. P represents atmospheric pressure. At time T, the pressure of the space 61 is equal to the atmospheric pressure P. At this time, it can be determined that the gap 62 is formed between the end portion of the substrate 2 and the substrate chuck 3.

FIG. 10B shows an example of a case in which only an operation of opening the space 61 to the atmosphere is performed in the third section where the fine moving stage 4 is stopped. The pressure of the space 61 drops once, and then becomes equal to the atmospheric pressure P at time T. At this time, it may be determined that the gap 62 is formed between the end portion of the substrate 2 and the substrate chuck 3.

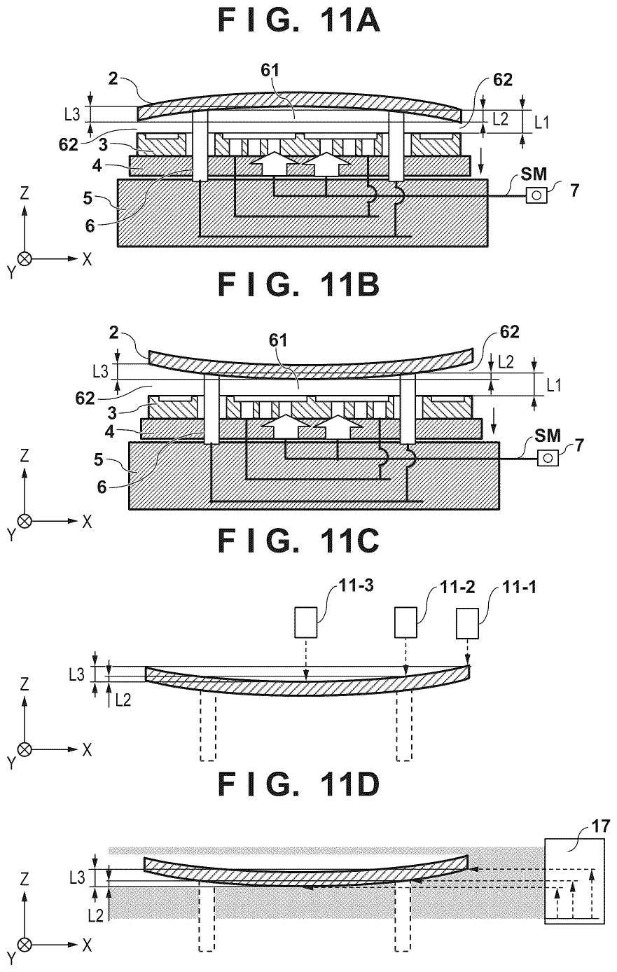

A method of performing gap detection based on the Z-direction relative position between the substrate 2 and the substrate chuck 3 and the warpage amount (deformation amount) of the substrate will be explained. Each of FIGS. 11A and 11B shows a state in which the gap 62 is present between the end portion of the substrate 2 and the substrate chuck 3 while the substrate 2 warps. FIG. 11A shows a case where the substrate 2 is convex upward, and FIG. 11B shows a case where the substrate 2 is convex downward. A distance L1 represents the Z-direction relative distance between the substrate holding surface of the substrate chuck 3 and the substrate holding surface of the pin member 6. A distance L2 represents the Z-direction relative distance between the Z-direction lower point of the substrate 2 and the substrate holding surface of the pin member 6. As shown in FIGS. 11A and 11B, when L1 is larger than L2, it can be determined that the gap 62 is formed between the end portion of the substrate 2 and the substrate chuck 3.

A distance L3 represents the distance between the Z-direction lowest point and the Z-direction highest point of the lower surface of the substrate 2, that is, the warpage amount of the substrate 2 while the substrate 2 is held by the pin members 6. Since the distance L2 is smaller than the distance L3, when the distance L1 is larger than the distance L3, it may be determined that the gap 62 is formed between the end portion of the substrate 2 and the substrate chuck 3. In many cases, the maximum value of the warpage amount of the substrate 2 with which the substrate chuck 3 can chuck the substrate 2 is decided according to the specifications of the substrate processing apparatus, which is, for example, 1 to 3 mm. FIG. 11C shows a specific example of a method of measuring the distances L2 and L3 using a distance sensor. In FIG. 11C, distance sensors 11-1, 11-2, and 11-3 are arranged at positions where they can measure the height of the outer peripheral position of the substrate 2, the height of the position where the substrate 2 is supported by the pin member 6, and the height of the central position of the substrate 2, respectively. During the measurement, the relative positions of the respective distance sensors are kept unchanged. If the plate thickness of the substrate 2 is known, the distance L2 can be decided from the difference between the measurement value of the distance sensor 11-1 and the measurement value of the distance sensor 11-2, and the distance L3 can be obtained from the difference between the measurement value of the distance sensor 11-1 and the measurement value of the distance sensor 11-3. Instead of the distance sensors 11-1, 11-2, and 11-3, a line sensor can be used for measurement. For example, FIG. 11D shows an example of measuring the distance L2 and the distance L3 using a line sensor 17 that can measure the height of an object and the distance from the object. In this manner, the line sensor 17 can measure the relative height and distance from the sensor for the peak of the warpage of the substrate 2, the position of the pin member 6, and the outer peripheral position. From the measurement results, the warpage amount and the warpage direction can be obtained. The distance sensors 11-1, 11-2, and 11-3 and the line sensor 17 may be arranged in the fine moving stage 4, or may be arranged in another unit. The timing for measuring the warpage of the substrate 2 is not limited to when the substrate 2 is mounted on the fine moving stage 4. The measurement may be performed at any point along the conveyance path of the substrate 2 to the fine moving stage 4. Also, the measurement may be performed before the substrate 2 is loaded into the apparatus, and the obtained value may be used.

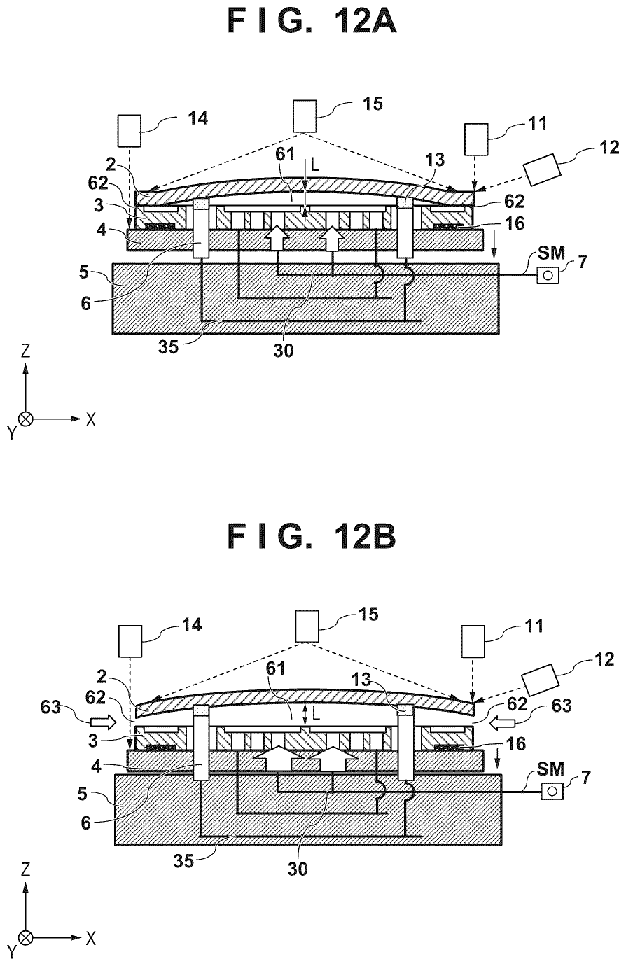

A method of performing gap detection based on the Z-direction position (height position) of the end portion of the substrate 2 will be explained. FIG. 12A shows a state in which the substrate 2 still adheres to the outer periphery of the substrate 3 when separating the substrate 2 from the substrate chuck 3 in the fourth section shown in FIG. 7. FIG. 12B shows a state in which the gap 62 is present between the end portion of the substrate 2 and the substrate chuck 3. A distance sensor 11 detects the Z-direction position of the outer peripheral portion of the substrate 2. The distance sensor 11 is installed in a location where its Z-direction position does not change even when the substrate 2 is moved in the Z direction. In FIG. 12A, the central portion of the substrate 2 is separated from the substrate chuck 3, and the outer periphery of the substrate 2, which the distance sensor 11 detects, still adheres to the substrate chuck 3. Accordingly, the Z-direction position of the outer periphery of the substrate 2 moves in the −Z direction together with the substrate chuck 3. To the contrary, in FIG. 12B, the outer periphery of the substrate 2, which the distance sensor 11 detects, is separated from the substrate chuck 3 so the Z-direction position of the outer periphery of the substrate 2 does not change. Accordingly, by detecting the change of the Z-direction position of the outer periphery of the substrate 2 by the distance sensor 11, it can be determined that the gap 62 is formed between the end portion of the substrate 2 and the substrate chuck 3. The position of the distance sensor 11 is not limited to the position shown in FIGS. 12A and 12B. For example, like the distance sensor 12, the distance sensor 11 may be arranged obliquely with respect to the outer peripheral portion of the substrate. On the other hand, when using the method of separating the substrate 2 from the substrate chuck 3 by moving the pin members 6 in the +Z direction, the Z-direction position of the end portion of the substrate 2 does not change until the gap 62 is formed. The Z-direction position of the end portion of the substrate 2 changes after the gap 62 is formed. Based on this change, it may be determined that the gap 62 is formed between the end portion of the substrate 2 and the substrate chuck 3.

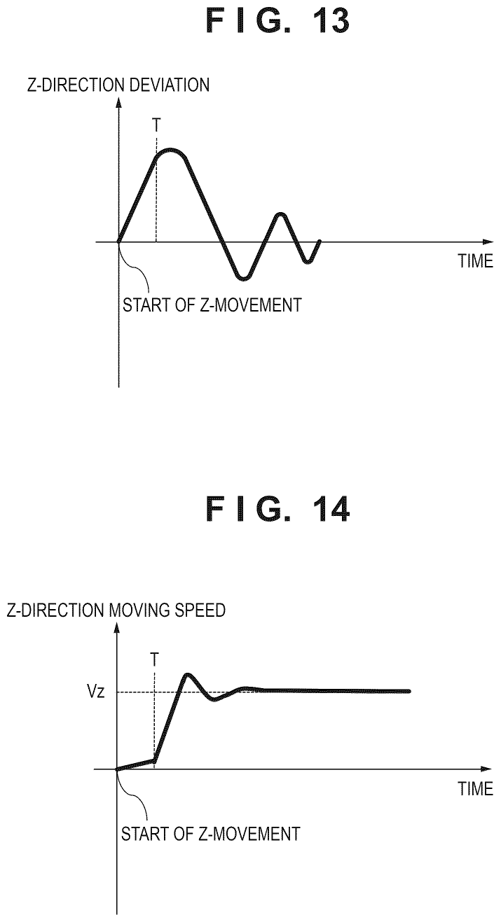

A method of performing gap detection based on the Z deviation of the driver will be explained. The Z deviation indicates the difference (control deviation) between the target value and the actual measured value of the Z-direction position of the driver that operates when separating the substrate 2 from the substrate chuck 3. In this embodiment, the fine moving stage 4 is moved in the -Z direction. Therefore, the actual measured value is obtained by, for example, measuring the Z-direction position of the fine moving stage 4 by using a distance sensor 14 as shown in FIGS. 12A and 12B. Also, the Z-direction position of the substrate chuck 3 may be measured using a distance sensor (not shown). The distance sensor may be an encoder. FIG. 13 shows an example of the temporal change of the Z deviation during a separation operation. The origin (the intersection of the ordinate and the abscissa) represents the point of time when the Z-driving for separating the substrate 2 from the substrate chuck 3 is started. If the initial state is one in which the substrate 2 and the substrate chuck 3 adhere to each other so that they are difficult to separate, the fine moving stage 4 cannot move to the target position instructed by the instruction unit 110. Hence, the target position and the actual position are different in the Z direction, and a Z deviation can be generated. In this case, when the substrate 2 and the substrate chuck 3 are separated at time T, the chucking force decreases and the difficulty in moving the fine moving stage 4 is eliminated. Accordingly, the moving speed in the Z direction increases to the target speed, which can lead to a decrease in the Z deviation. In this manner, the timing when the gap 62 is formed between the substrate 2 and the substrate chuck 3 can be determined based on the change of the Z deviation. When using the method of separating the substrate 2 from the substrate chuck 3 by moving the pin members 6 in the +Z direction, the Z deviation may be measured based on the Z-direction position of the substrate 2 detected by the distance sensor 11. In FIGS. 12A and 12B, the Z-direction position of the outer peripheral portion of the substrate 2 is measured. However, the present disclosure is not limited to this, and the Z-direction position may be measured at a measurement point closer to the center of the substrate 2.

A method of detecting the gap based on the moving speed of the driver will be explained. The moving speed of the driver refers to the relative moving speed in the Z direction (Z-direction moving speed) between the substrate chuck 3 and the substrate 2 (pin member 6) by the driver when separating the substrate 2 from the substrate chuck 3. The Z-direction moving speed may be obtained by measuring the Z-direction position of the fine moving stage 4, like the distance sensor 14 shown in FIGS. 12A and 12B. Also, the Z-direction moving speed may be obtained by measuring the Z-direction position of the substrate chuck 3 by using a sensor (not shown). The sensor may be an encoder. FIG. 14 shows an example of the Z-direction moving speed during a separation operation. In FIG. 14, Vz represents the target speed instructed by the instruction unit 110. The origin (the intersection of the ordinate and the abscissa) represents the point of time when the Z-driving for separating the substrate 2 from the substrate chuck 3 is started. If the initial state is one in which the substrate 2 and the substrate chuck 3 adhere to each other so that they are difficult to separate, the moving speed of the fine moving stage 4 can be lower than the target speed instructed by the instruction unit 110. In this case, when the substrate 2 and the substrate chuck 3 are separated at time T, the chucking force decreases and the difficulty in moving the fine moving stage 4 is eliminated. Then, the moving speed in the Z direction can rise to the target speed. In this manner, the timing when the gap 62 is formed between the end portion of the substrate 2 and the substrate chuck 3 can be determined based on the change of the Z-direction moving speed. When using the method of separating the substrate 2 from the substrate chuck 3 by moving the pin members 6 in the +Z direction, the Z-direction moving speed may be measured based on the Z-direction position of the substrate 2 detected by the distance sensor 11. In FIGS. 12A and 12B, the Z-direction position of the outer peripheral portion of the substrate 2 is measured. However, the present disclosure is not limited to this, and the Z-direction position may be measured at a measurement point closer to the center of the substrate 2.

The gap may be detected based on the acceleration of the driver. In this case, the acceleration may be obtained from the speed of the fine moving stage 4 or the substrate chuck 3. Also, an accelerometer may be installed in the driver, and the acceleration may be measured by the accelerometer. When the substrate 2 is separated from the substrate chuck 3, the speed of the driver can change. In this case, the change of the acceleration can be detected. In this manner, the timing when the gap 62 is formed between the end portion of the substrate 2 and the substrate chuck 3 may be determined based on the change of the acceleration in the Z direction.

A method of performing gap detection based on the driving force will be explained. The driving force refers to a force generated when the driver moves in the Z direction to separate the substrate 2 from the substrate chuck 3. If the force acting between the substrate 2 and the substrate chuck 3 changes before and after the gap 62 is formed, the driving force can also change. For example, when separating the substrate chuck 3 from the substrate 2 by-Z driving, if the substrate 2 and the substrate chuck 3 adhere to each other so that they are difficult to separate, the initial driving force in-Z driving is large. Subsequently, when the substrate 2 and the substrate chuck 3 are separated, the chucking force decreases and the difficulty in moving the fine moving stage 4 is eliminated. Accordingly, the driving force can decrease. In this manner, based on the change of the driving force, it can be detected that the gap 62 is formed between the end portion of the substrate 2 and the substrate chuck 3. When using a method in which the driver generates the driving force by power, the drive current changes in accordance with the driving force. Therefore, the timing when the gap 62 is formed between the end portion of the substrate 2 and the substrate chuck 3 may be determined based on the drive current.

A method of performing gap detection based on the load applied on the pin member 6 will be explained. FIG. 12A shows a state in which the substrate 2 and the substrate chuck 3 adhere to each other, and FIG. 12B shows a state in which the gap 62 is present between the substrate 2 and the substrate chuck 3. A load sensor 13 that detects the load applied by the substrate 2 is installed in the pin member 6. The load sensor 13 may be a piezoelectric element or a strain gauge. For example, if the initial state is one in which the substrate 2 and the substrate chuck 3 adhere to each other so that they are difficult to separate, the load detected by the load sensor 13 provided in the pin member 6 can be larger than the weight of the substrate 2. Subsequently, when the substrate 2 and the substrate chuck 3 are separated, the chucking force acting between the substrate 2 and the substrate chuck 3 decreases, and the load applied on the load sensor 13 can decrease to the weight of the substrate 2. In this manner, the timing when the gap 62 is formed between the end portion of the substrate 2 and the substrate chuck 3 can be determined based on the change of the load applied on the pin member 6.

A method of performing gap detection based on the change of the distortion (deformation amount) of the substrate 2 will be explained. FIG. 12A shows a state in which the substrate 2 and the substrate chuck 3 adhere to each other, and FIG. 12B shows a state in which the gap 62 is present between the end portion of the substrate 2 and the substrate chuck 3. A distortion sensor 15 that measures the distortion of the substrate 2 in the Z direction is arranged above the substrate 2. The distortion sensor 15 can be an optical distance sensor, an interferometer, an image capturing apparatus, or the like. The distortion measurement range by the distortion sensor 15 may cover the entire upper surface of the substrate 2, or may cover only a portion where a distortion change is easy to find. The portion where a distortion change is easy to find can be, for example, a portion near the outer periphery of the substrate 2 or a portion near the pin member 6.

The distortion change in the upper surface of the substrate 2 will be explained. First, in a state in which the substrate 2 and the pin member are not in contact, the upper surface of the substrate 2 is nearly flat. When the fine moving stage 4 starts-Z driving, if the substrate 2 and the substrate chuck 3 adhere to each other so that they are difficult to separate, the pin member 6 pushes up the substrate 2 adhering to the substrate chuck 3. Hence, the upper surface of the substrate 2 is distorted such that only the portion around the pin member bulges. Subsequently, when the gap 62 is formed between the end portion of the substrate 2 and the substrate chuck 3, the chucking force between the substrate 2 and the substrate chuck 3 disappears, and the local bulging of the surface of the substrate 2 around the pin member 6 is eliminated. In this manner, the timing when the gap 62 is formed between the end portion of the substrate 2 and the substrate chuck 3 can be determined by the distortion sensor 15 detecting the distortion change in the upper surface of the substrate 2.

A method of detecting the gap based on the change of the distortion (deformation amount) of the substrate chuck 3 will be explained. FIG. 12A shows a state in which the substrate 2 and the substrate chuck 3 adhere to each other, and FIG. 12B shows a state in which the gap 62 is present between the end portion of the substrate 2 and the substrate chuck 3. A distortion sensor 16 that detects the distortion of the substrate chuck 3 is installed in the substrate chuck 3. The distortion sensor 16 can be a piezoelectric element or a strain gauge. In FIGS. 12A and 12B, the distortion sensor 16 is installed on the lower side of the substrate chuck 3. However, the position is not limited to this, and the distortion sensor 16 can be installed at any position where it does not interfere with the substrate chuck 3 holding the substrate 2. For example, the distortion sensor 16 may be embedded inside the chuck, or the distortion sensor 16 may be installed on the side surface of the chuck.

If the initial state is one in which the substrate 2 and the substrate chuck 3 adhere to each other so that they are difficult to separate, attempting to forcibly separate the substrate 2 adhering to the substrate chuck 3 therefrom using the pin members 6 may cause a distortion of the substrate chuck 3, which can be detected by the distortion sensor 16. Subsequently, when the gap 62 is formed between the end portion of the substrate 2 and the substrate chuck 3, the chucking force between the substrate 2 and the substrate chuck 3 disappears, so the substrate chuck 3 is no longer pulled by the substrate 2, and the distortion of the substrate chuck 3 can decrease. The distortion sensor 16 can detect this. In this manner, the timing when the gap 62 is formed between the end portion of the substrate 2 and the substrate chuck 3 can be determined by the distortion sensor 16 provided in the substrate chuck 3.

During the gas supply, which is performed when the gap detection means (detector) detects that the gap 62 is present, the controller 100 can change the gas supply amount in accordance with the progress of the operation of separating the substrate 2 and the substrate chuck 3 by the driver. Various examples of the gas supply control after the gap 62 is formed in this embodiment will be explained below. However, the same control may be applicable even before the gap 62 is formed.

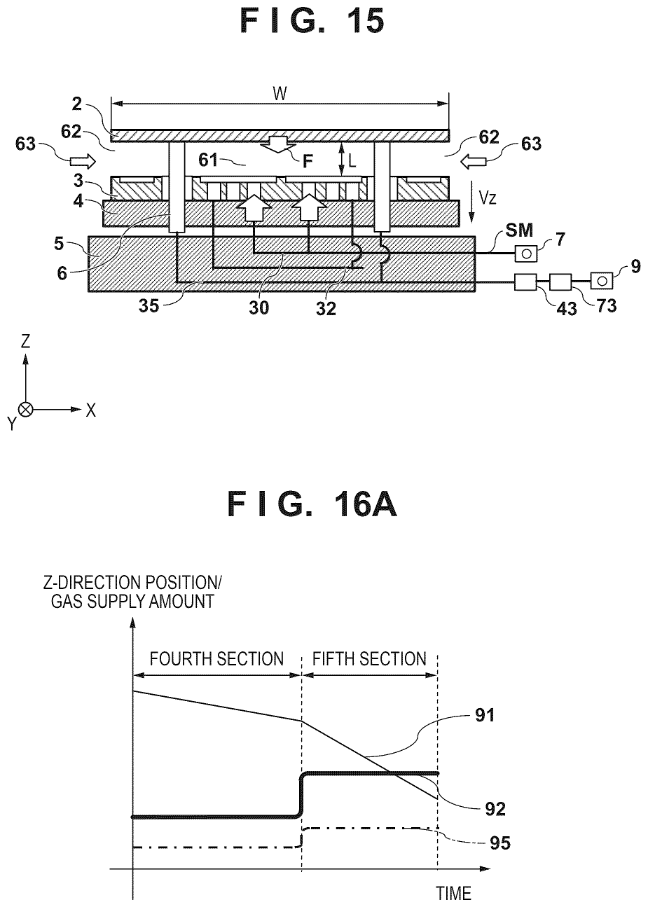

The gas supply control can be performed based on the relative moving speed between the substrate chuck 3 and the pin member 6. FIG. 15 is a schematic view showing an example of the configuration of the substrate stage 1, and FIG. 15 shows a state in which the fine moving stage 4 is moving in the −Z direction at a speed Vz. A chucking force F generated between the substrate 2 and the substrate chuck 3 during movement in the −Z direction is generated when the gas supply amount to the space 61 is insufficient with respect to the capacity expansion of the space 61. Therefore, by supplying the gas from the supply mechanism SM at a speed corresponding to the capacity expansion of the space 61, the chucking force F can be reduced. Letting W be the diameter of the substrate 2 and L be the distance between the substrate 2 and the substrate chuck 3, a capacity expansion amount Q of the space 61 per unit time is expressed by the following:

$$Q = {W}^{2} \times L \times Vz / 4.$$

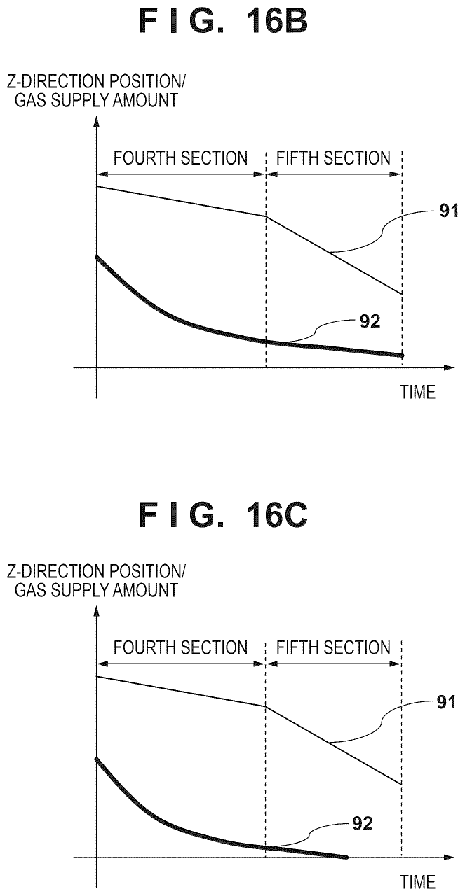

In this manner, the volume expansion amount Q of the space 61 per unit time is proportional to the speed Vz of the fine moving stage 4. Therefore, the gas supply amount from the supply mechanism SM may be changed in proportion to the speed Vz. FIG. 16A shows an example of the temporal change of the Z-direction position 91 of the fine moving stage 4, the temporal change of a Z-direction speed 95 of the fine moving stage 4, and the temporal change of the gas supply amount 92 during an operation of separating the substrate 2 and the substrate chuck 3. Note that in FIG. 16A, the speed of the fine moving stage 4 is constant in each of the fourth section and the fifth section. However, the present disclosure is not limited to this, and the speed may be changed in each section. In that case, the gas supply amount may be changed in accordance with the fluctuations. Also, speed data may be collected for each processing of the substrate 2, and the gas supply amount from the supply mechanism SM may be decided based on the collected past data.

The gas supply control can be performed based on the size of the gap 62 between the end portion of the substrate 2 and the substrate chuck 3. While the fine moving stage 4 is moving in the −Z direction, the gas 63 is supplied to the space 61 from the gap 62 between the end portion of the substrate 2 and the substrate chuck 3. Since the gas supply amount is insufficient, a negative pressure is generated in the space 61. The reason for this is that, when the gap 62 is narrow, the flow velocity of the gas 63 flowing into the gap 62 increases, and this increases a pressure loss and leads to a delay in gas supply to the space 61. Hence, if the pressure loss is small, the chucking force F also becomes small. For example, a flow velocity v of the gas 63 is obtained by dividing the capacity expansion amount Q of the space 61 per unit time by the product of the area of the gap 62, that is, a peripheral length 2πW of the substrate 2 and the distance L between the substrate 2 and the substrate chuck 3. That is, the flow velocity v of the gas 63 is expressed by the following:

$$\begin{matrix}v = Q / ( 2 π W \times L ) \\ = W \times Vz / 8 L .\end{matrix}$$

A pressure loss p is proportional to the square of the flow velocity v according to the Darcy-Weisbach equation. That is,

$$p = {( W \times Vz / 8 L )}^{2} .$$

From the above equation, the pressure loss p is proportional to the reciprocal of the square of the distance L between the substrate 2 and the substrate chuck 3. Hence, it can be seen that the pressure loss p is very large at the beginning of the separation operation when the distance L between the substrate 2 and the substrate chuck 3 is close to zero, and then decreases rapidly as the distance L increases. Therefore, the gas supply amount from the supply mechanism SM may be decreased nonlinearly as the distance L increases. FIG. 16B shows an example of the temporal change of the Z-direction position 91 of the fine moving stage 4 and the temporal change of the gas supply amount 92 during the operation of separating the substrate 2 and the substrate chuck 3. As the distance L increases, only the gas 63 supplied through the gap 62 (FIG. 15) between the end portion of the substrate 2 and the substrate chuck 3 may be sufficient to compensate for the capacity expansion of the space 61. In that case, as shown in FIG. 16C, the gas supply may be stopped before the fine moving stage 4 reaches the final Z-direction position (that is, before the operation of separating the substrate 2 and the substrate chuck 3 is stopped). Also, while the fine moving stage 4 is moving in the −Z direction, the Z-direction distance L of the gap 62 between the end portion of the substrate 2 and the substrate chuck 3 may be monitored, and the gas supply amount may be decided based on the obtained value. Also, the value data of the distance L may be collected for each processing of the substrate 2, and the gas supply amount from the supply mechanism SM may be decided based on the collected past data.

Since the negative pressure of the space 61 is the factor that generates the chucking force F, the pressure of the space 61 may be monitored, and the gas supply amount from the supply mechanism SM may be changed accordingly. FIG. 17 shows an example of the configuration in which the pressure sensor 10 is installed in a system communicating with the space 61 to measure the pressure of the space 61 in the substrate stage 1. In FIG. 17, the pressure sensor 10 is provided outside the substrate stage 1. However, the present disclosure is not limited to this, and the pressure sensor 10 may be provided inside the substrate stage 1.

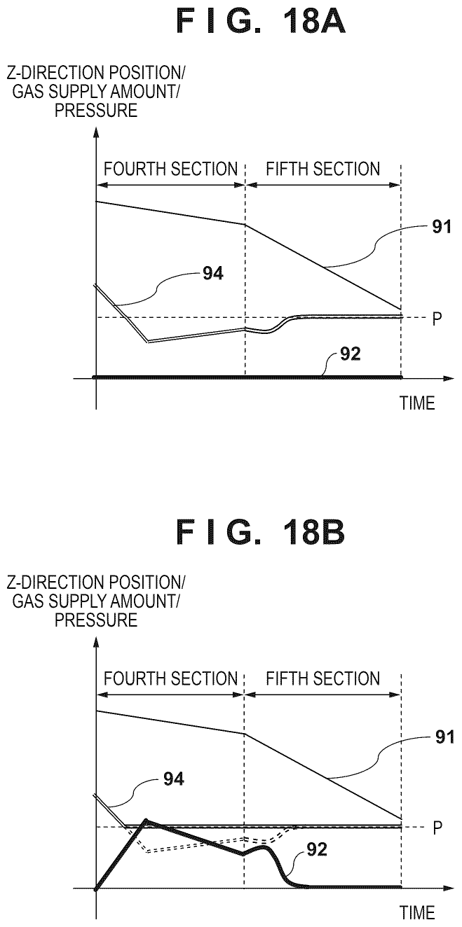

FIG. 18A shows the change of the Z-direction position 91 of the fine moving stage 4, the change of the gas supply amount 92, and the change of the pressure 94 of the space 61 during the operation of separating the substrate 2 from the substrate chuck 3. The pressure P represents atmospheric pressure. Since gas supply is not performed, the gas supply amount 92 is zero. It can be seen that a negative pressure is generated in each of the fourth section and the fifth section. To eliminate the negative pressure, a gas may be supplied from the supply mechanism SM to the range where the negative pressure is generated. FIG. 18B shows an example of a case where a gas is supplied from the supply mechanism SM in accordance with the pressure of the space 61 detected by the pressure sensor 10. In FIG. 18A, even when the gas supply amount 92 is zero, the pressure of the space 61 becomes equal to atmospheric pressure P from the middle of the fifth section. This means that a negative pressure is not generated between the substrate 2 and the substrate chuck 3 even without supplying a gas. In this case, as shown in FIG. 18B, the gas supply from the supply mechanism SM may be stopped. Also, pressure value data of the space 61 may be collected for each processing of the substrate 2, and the gas supply amount from the supply mechanism SM may be decided based on the collected past data.

During the operation of separating the substrate 2 from the substrate chuck 3, the driving force of the driver (fine moving stage 4) may be monitored, and the gas supply amount may be changed in accordance with the driving force. The drive current value may be monitored as a parameter representing the driving force. For example, the drive current value during the operation is measured in advance while there is no chucking force between the substrate 2 and the substrate chuck 3, and the obtained value is used as a reference value. If the drive current value is higher than the reference value, this indicates that a chucking force is generated between the substrate 2 and the substrate chuck 3, so that the gas supply amount from the supply mechanism SM to the space 61 may be increased. Even when the gas is not supplied from the supply mechanism SM, if the drive current value is equal to the reference value, this indicates that there is no chucking force between the substrate 2 and the substrate chuck 3. Thus, setting the gas supply amount from the supply mechanism SM to the space 61 may be unnecessary. Also, drive current value data may be collected for each processing of the substrate 2, and the gas supply amount from the supply mechanism SM may be decided based on the collected past data.

As shown in FIGS. 12A and 12B, the load sensor 13 for detecting the load applied by the substrate 2 may be installed in the pin member 6, and the gas supply amount may be changed in accordance with the load detected by the load sensor 13. The load sensor 13 may be a piezoelectric element or a strain gauge. In a state in which there is no chucking force between the substrate 2 and the substrate chuck 3, the load applied from the substrate 2 on the pin member 6 during the operation is measured in advance by the load sensor 13, and the obtained value is used as a reference value. If the load is higher than the reference value, this indicates that a chucking force is generated between the substrate 2 and the substrate chuck 3, so that the gas supply amount from the supply mechanism SM to the space 61 may be increased. Even when the gas is not supplied from the supply mechanism SM, if the load detected by the load sensor 13 is equal to the reference value, this indicates that there is no chucking force between the substrate 2 and the substrate chuck 3. Thus, the gas supply amount from the supply mechanism SM to the space 61 may be set unnecessary. Also, load data from the load sensor 13 may be collected for each processing of the substrate 2, and the gas supply amount from the supply mechanism SM may be decided based on the collected past data.

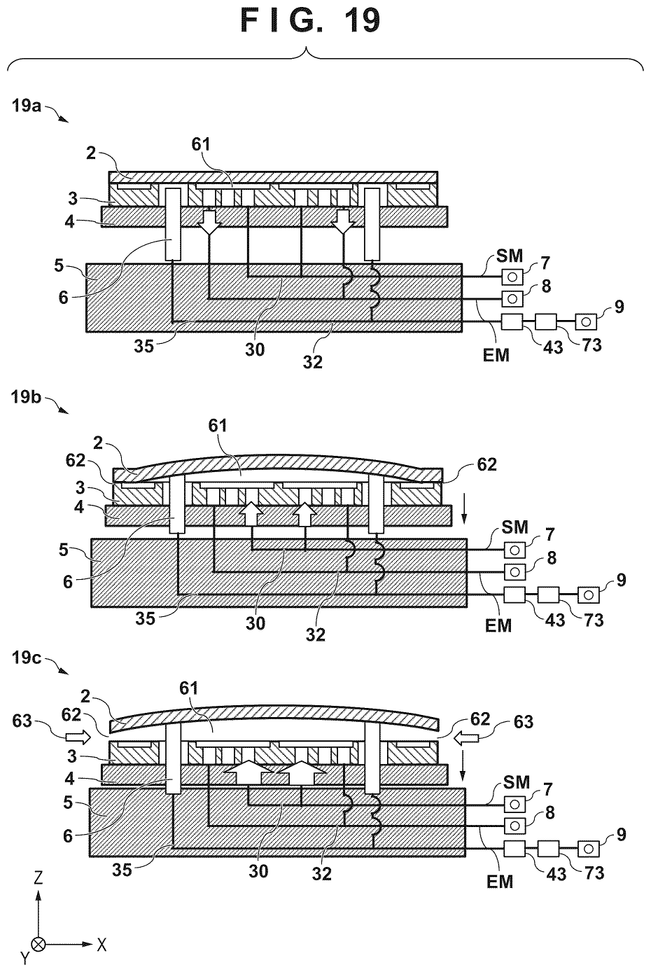

The chucking force in the space 61 can change in accordance with the shape of the substrate 2. Therefore, the warpage amount (deformation amount) of the substrate 2 may be measured during the operation of separating the substrate 2 from the substrate chuck 3, and the gas supply amount may be changed in accordance with the warpage amount. With reference to FIG. 19, a case where the substrate 2 is convex upward will be explained. In FIG. 19, a state 19a shows a state in which the substrate 2 is chucked by the substrate chuck 3. The substrate 2 is in tight contact with the substrate chuck 3 due to chucking by the exhaust mechanism EM. A state 19b shows the initial state of movement in the −Z direction when separating the substrate 2 from the substrate chuck 3. Due to the upward convex shape of the substrate 2, the outer periphery of the substrate 2 and the substrate chuck 3 still adhere to each other, and the gap 62 is closed. Accordingly, the space 61 is isolated from the space around the substrate chuck 3. In this state, when the fine moving stage 4 moves in a direction of separating the substrate 2 and the substrate chuck 3, the space 61 expands and a negative pressure is generated. To eliminate the negative pressure, it is necessary to supply the gas from the supply mechanism SM. When the substrate 2 is flat, the gap 62 is present between the end portion of the substrate 2 and the substrate chuck 3, and the surrounding gas 63 is also supplied through the gap 62. However, this does not occur when the substrate is convex upward, so that the supply amount required to eliminate the negative pressure of the space 61 increases as compared to the case where the substrate is flat. Therefore, the gas supply amount from the supply mechanism SM may be increased as compared to the case where the substrate is flat. The state after the fine moving stage 4 is further moved in the −Z direction is shown as a state 19c. Here, the gap 62 is present between the end portion of the substrate 2 and the substrate chuck 3, and the surrounding gas 63 is supplied through the gap 62 to the space 61. However, due to the upward convex shape of the substrate 2, the gap 62 is narrower than when the substrate 2 is flat. Therefore, the amount of the surrounding gas 63 supplied to the space 61 decreases as compared to the case where the substrate is flat. Accordingly, the gas supply amount from the supply mechanism SM may be increased as compared to the case where the substrate is flat.

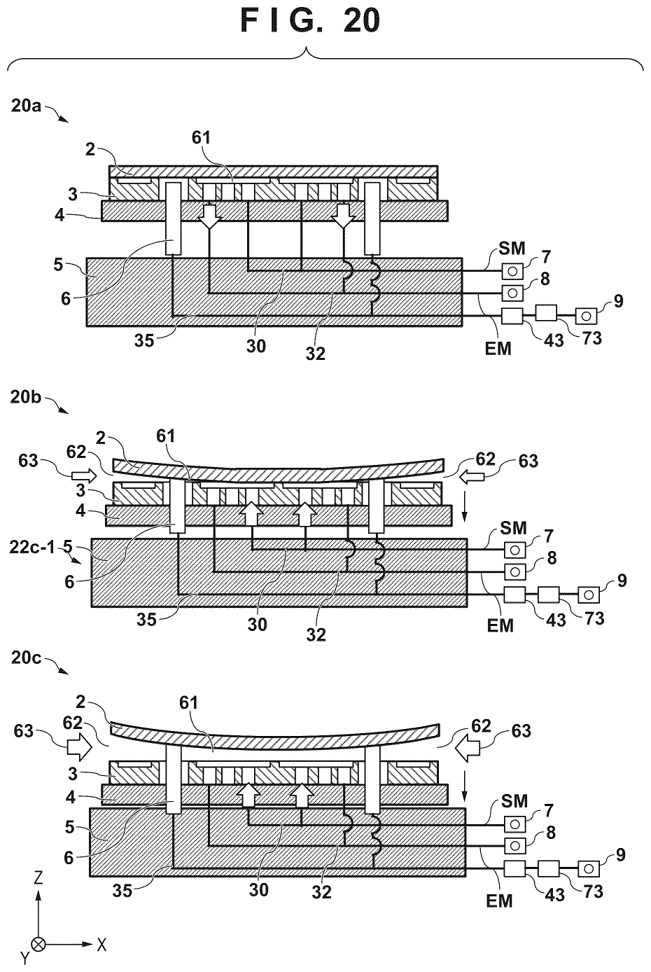

With reference to FIG. 20, a case where the substrate 2 is convex downward will be explained. In FIG. 20, a state 20a shows a state in which the substrate 2 is chucked by the substrate chuck 3. The substrate 2 is in tight contact with the substrate chuck 3 due to chucking by the exhaust mechanism EM. A state 20b shows the initial state of movement in the −Z direction when separating the substrate 2 from the substrate chuck 3. Due to the downward convex shape of the substrate 2, the gap 62 is present between the end portion of the substrate 2 and the substrate chuck 3, and the size thereof is larger than when the substrate 2 is flat. In this state, when the fine moving stage 4 moves in a direction of separating the substrate 2 and the substrate chuck 3, the amount of the surrounding gas 63 supplied through the gap 62 increases as compared to the case where the substrate 2 is flat. Therefore, the gas supply amount from the supply mechanism SM to eliminate the negative pressure of the space 61 may be reduced as compared to the case where the substrate 2 is flat. The state after the fine moving stage 4 is further moved in the −Z direction is shown as a state 2 0c. Here, the gap 62 is present between the end portion of the substrate 2 and the substrate chuck 3, and the surrounding gas 63 is supplied through the gap 62 to the space 61. Since the gap 62 at this time is also wider than when the substrate 2 is flat, the amount of the surrounding gas 63 supplied to the space 61 increases as compared to the case where the substrate is flat. Accordingly, the gas supply amount from the supply mechanism SM may be reduced as compared to the case where the substrate is flat.

The optimal gas supply amount can also change in accordance with the strength of the substrate 2. For example, if the gas supply amount from the supply mechanism SM to the space 61 is increased, the pressure of the space 61 rises, and this can increase the speed of separating the substrate 2 and the substrate chuck 3. This is advantageous in shortening the time required to unload the substrate 2 from the substrate chuck 3. However, if the strength of the substrate 2 is low, excessive pressure can damage the substrate 2. Therefore, the gas supply amount from the supply mechanism SM to the space 61 may be changed based on the characteristics that decide the strength of the substrate 2. The characteristics that decide the strength of the substrate 2 include at least one of the material, thickness, processed state, and size of the substrate 2.

The gas supply amount from the supply mechanism SM may be decided based on at least two of a plurality of characteristics described above. The plurality of characteristics described so far are listed below:
the speed at which the substrate 2 and the substrate chuck 3 are relatively moved in separate directions,
the size of the gap 62 between the end portion of the substrate 2 and the substrate chuck 3,
the pressure of the space 61 between the substrate 2 and the substrate chuck 3,
the driving force when the substrate 2 and the substrate chuck 3 are relatively moved in separate directions,
the shape of the substrate 2, and
the strength of the substrate 2.

Also, data of at least one of these characteristics may be collected for each substrate processing, and the gas supply amount from the supply mechanism SM may be decided based on the results of calculation processing performed on the collected past data.

In this embodiment, in a case where the temperature of the gas supplied from the supply mechanism SM is different from the temperature of the gas around the substrate chuck 3, supplying an excessive amount of gas from the supply mechanism SM may cause the temperature of the gas around the substrate chuck 3 to change. However, depending on the type of substrate processing apparatus, the change of the gas temperature around the substrate chuck 3 may affect the quality of the substrate processing. For example, in an exposure apparatus, if the ambient temperature of the substrate chuck 3 changes, then the size of the substrate 2 changes due to heat. If the ambient temperature is higher than normal, then the substrate 2 is exposed while it expands due to heat. Then, when the thermal expansion disappears, the exposed pattern becomes smaller than intended. To the contrary, if the ambient temperature is lower than normal, the exposed pattern becomes larger than intended.

Furthermore, when the gas flow rate is high, the airflow around the substrate chuck 3 may change. This may also affect the quality of the substrate processing. For example, when using an interferometer to measure the position of a fine moving stage 4, if gases with different temperatures are mixed on the optical path of the interferometer, the refractive index of the gas fluctuates, which can deteriorate the distance measurement accuracy of the interferometer. Hence, an excessive gas supply by the supply mechanism SM can cause this phenomenon.

In this manner, if the gas supply from the supply mechanism SM affects the substrate processing quality, the gas supply from the supply mechanism SM may be stopped before the chucking force between the substrate 2 and the substrate chuck 3 is eliminated.

As described above, the control method of the substrate stage 1 according to this embodiment includes a step of detecting a gap between the end portion of the substrate and the substrate chuck in an operation of separating the substrate and the substrate chuck by a driver. The control method also includes a step of controlling gas supply by a supplier based on a result of detection by a detector.

### Second Embodiment

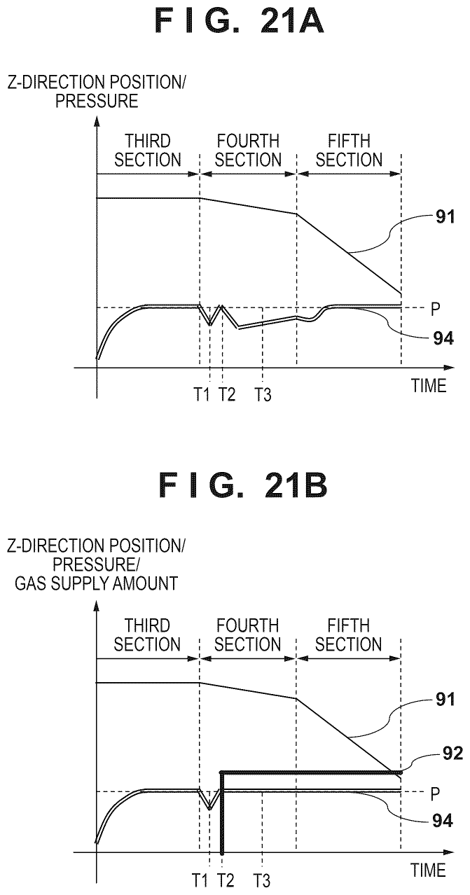

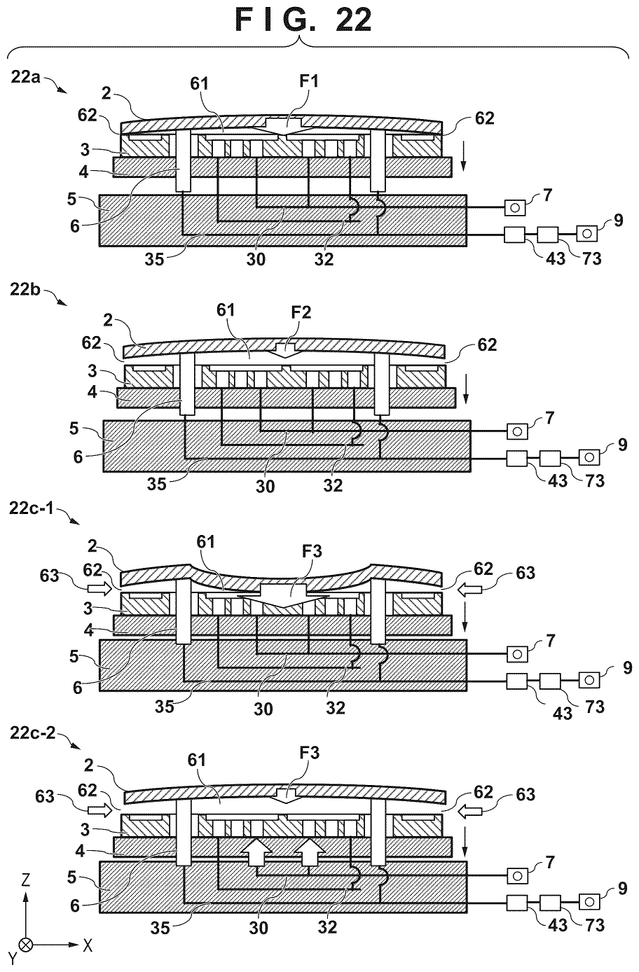

In the first embodiment, the case has been explained in which, in the third section, the chucking between the substrate 2 and the substrate chuck 3 is canceled by supplying a pressured gas. However, the chucking may be canceled by opening the space to the atmosphere. In the second embodiment, this case will be explained with reference to FIGS. 21A to 22.

FIG. 21A shows the change of a Z-direction position 91, the change of a gas supply amount 92, and the change of a pressure 94 between the substrate 2 and the substrate chuck 3 from the middle of the third section to the fifth section (FIG. 7) according to a conventional technique. P represents atmospheric pressure. In FIG. 21A, T1 indicates an early timing in the fourth section. The state of a fine moving stage 4 at this timing is shown as a state 22a in FIG. 22. Here, a gap 62 is closed so that a space 61 is isolated from the space around the substrate chuck 3. In this state, when the fine moving stage 4 moves in a direction of separating the substrate 2 and the substrate chuck 3, the space 61 expands and a negative pressure is generated in the space 61. Therefore, a chucking force by the negative pressure and a force F1 corresponding to the weight of the substrate 2 are generated on the substrate 2 in the direction approaching the substrate chuck 3.

In FIG. 21A, T2 indicates a timing when the pressure of the space 61 becomes equal to atmospheric pressure. The state of the fine moving stage 4 at this timing is shown as a state 22b in FIG. 22. Here, since the fine moving stage 4 is moved in the −Z direction, the gap 62 is formed between the end portion of the substrate 2 and the substrate chuck 3, and this releases the negative pressure. Accordingly, the pressure of the space 61 becomes equal to atmospheric pressure. Therefore, a force F2 corresponding to the weight of the substrate 2 is generated on the substrate 2 in a direction of approaching the substrate chuck 3. Thus, chucking does not occur between the substrate 2 and the substrate chuck 3. Hence, at this point of time, the gas supply from the supply mechanism SM is stopped.

The state of the fine moving stage 4 at T3 in FIG. 21A is shown as a state c-1 in FIG. 22. The state of the fine moving stage 4 at T3 in FIG. 21B is shown as a state c-2 in FIG. 22. A countermeasure against the chucking force generated by the movement of the fine moving stage 4 is similar to that in the first embodiment. The subsequent explanation is omitted to avoid repetition.

### Third Embodiment

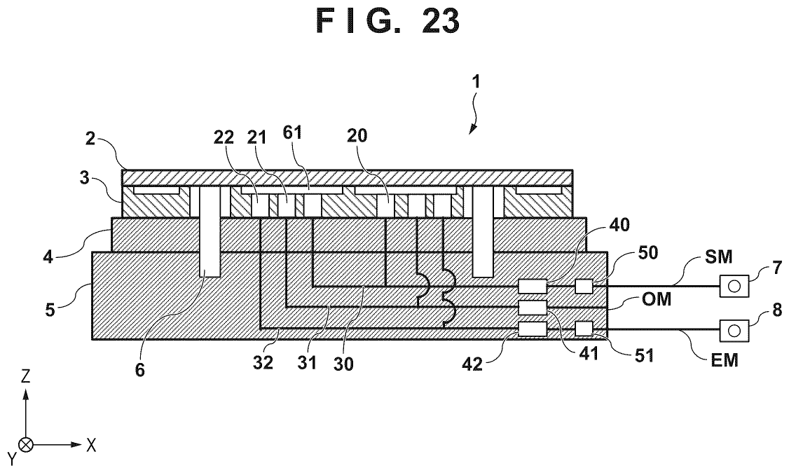

FIG. 23 shows the configuration of a substrate stage 1 according to the third embodiment. The substrate stage 1 includes an open mechanism OM that can be controlled independently and opens a space 61 to the atmosphere, separate from an exhaust mechanism EM and a supply mechanism SM. In an operation of separating a substrate 2 and a substrate chuck 3 by a driver, a controller 100 can further control opening and closing of the open mechanism OM.

The open mechanism OM is a mechanism for causing the space 61 (first space) to communicate with a stage space, and includes a flow path (pipe) 31 (second flow path) and a solenoid valve 41 (second valve).

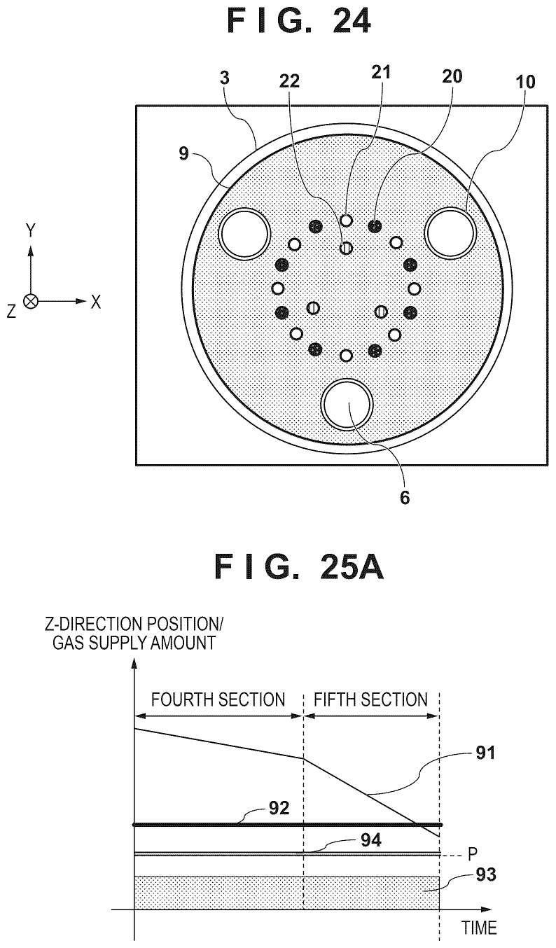

FIG. 24 is a plan view of the substrate chuck 3 when viewed from the +Z direction. In FIG. 24, a supply hole 20 continuous with a flow path 30, an open hole 22 continuous with a flow path 32, and an exhaust hole 21 continuous with the flow path 31 are formed in the substrate chuck 3.

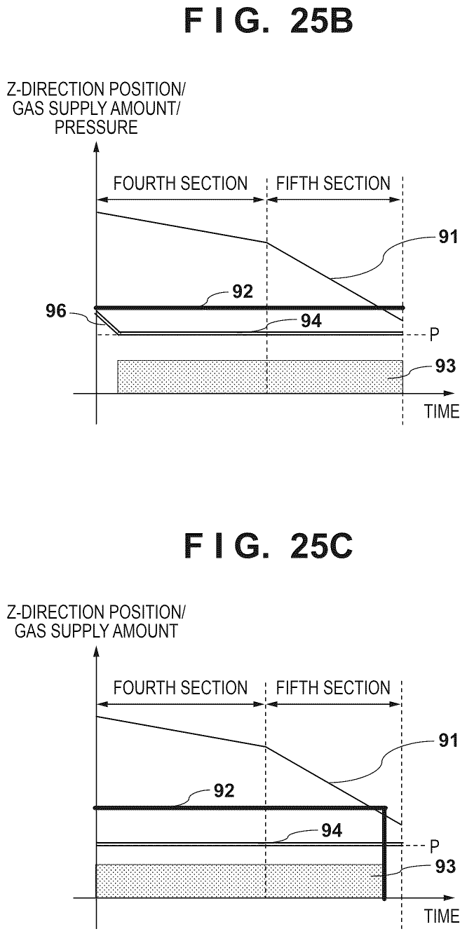

FIGS. 25A to 25C are views each showing a substrate unload profile in a case of using the open mechanism OM. A solid line 91 represents the Z-direction relative position between a fine moving stage 4 and a pin member 6, a solid line 92 represents the gas supply amount from the supply mechanism SM to the space 61, a double line 94 represents the pressure of the space 61, and hatching 93 represents that the open mechanism OM is in an open state. For example, as shown in FIG. 25A, the controller 100 may open the open mechanism OM at the same time as the start of the gas supply from a positive-pressure tank 7 to the space 61. The controller 100 may close the open mechanism OM at the same time as the end of the gas supply from the positive-pressure tank 7 to the space 61. In this manner, the controller 100 can match the open and close timings of the open mechanism OM with the start and end timings of the gas supply, respectively. With this, the gas supply amount is increased by the supply mechanism SM and the opening of the open mechanism OM, allowing the vacuum of the space 61 to be released quickly.

However, if the pressure of the space 61 becomes higher than the pressure around the chuck in a state in which the open mechanism OM is opened (turned on) at the same time as the gas supply from the supply mechanism SM, a flow occurs in which the gas supplied from the supply mechanism SM is exhausted from the open mechanism OM. If the pressure of the space 61 rises to the same level as the pressure around the chuck, it becomes difficult to further increase the pressure of the space 61. However, in the early stage of the relative movement between the fine moving stage 4 and the pin members 6, the amount of gas supply 63 from around the chuck is small because a gap 62 is narrow. Thus, a negative pressure is likely to be generated in th space 61. Therefore, it may be preferable to pre-set the pressure of the space 61 to a higher level in the early stage. To achieve this, only in the early stage of Z-moving for separating the substrate 2 and the substrate chuck 3, the gas may be supplied from the supply mechanism SM while the open mechanism OM is closed (off), and thereafter the gas may be supplied simultaneously from both the supply mechanism SM and the open mechanism OM to increase the supply amount. That is, after the gas supply by the supply mechanism SM is started, the open mechanism may be opened. FIG. 25B shows a case where the pressure of the space 61 rises in a section 96 since the open mechanism OM is closed (off) in the early stage of the fourth section. The timing of opening the open mechanism OM may be when it is determined by any one of the gap detection means according to this embodiment that the gap 62 is formed between the end portion of the substrate 2 and the substrate chuck 3.

In the later stage of the relative movement between the fine moving stage 4 and the pin members 6, the amount of gas supply 63 from around the chuck increases because the gap 62 is wide. Thus, the gas supply amount from the supply mechanism SM and the open mechanism OM to the space 61 may be small. Therefore, as shown in FIG. 25C, the gas supply from each of the supply mechanism SM and the open mechanism OM may be stopped before the relative movement between the fine moving stage 4 and the pin members 6 ends. For example, in this embodiment, the controller 100 controls the driver so as to set the relative moving speed between the substrate chuck 3 and the pin members 6 to the first speed in the fourth section after the substrate 2 and the pin members 6 contact each other, and then set the relative moving speed to the second speed higher than the first speed in the fifth section. Here, after the substrate 2 and the pin members 6 contact in the operation of separating the substrate 2 and the substrate chuck 3, the controller 100 stops the gas supply by the supply mechanism SM and closes the open mechanism OM in the middle of the section (fifth section) where the second speed is set. In FIG. 25C, the supply mechanism SM and the open mechanism OM are stopped simultaneously. However, the present disclosure is not limited to this. To decrease the gas supply amount to the space 61, the gas supply from the supply mechanism SM may be stopped before the open mechanism OM is closed. Conversely, the open mechanism OM may be closed before the supply mechanism SM is stopped. This also achieves the same effect.

### Embodiment of Article Manufacturing Method

An article manufacturing method according to an embodiment is suitable for manufacturing an article, for example, a microdevice such as a semiconductor device or an element having a microstructure. The article manufacturing method according to the present embodiment can include a forming step of forming an original plate pattern onto a substrate by using the above-described exposure apparatus (lithography apparatus) and a processing step of processing the substrate on which the pattern is formed in the forming step. The manufacturing method further can include other known steps (oxidation, film formation, deposition, doping, planarization, etching, resist removal, dicing, bonding, packaging, and the like). The article manufacturing method of this embodiment is more advantageous than the conventional methods in at least one of the performance, quality, productivity, and production cost of the article.

According to the various embodiments described above, it is possible to provide techniques advantageous in terms of wear resistance of a substrate chuck regarding cancelation of the holding of a substrate by the substrate chuck.

While the present disclosure has described example embodiments, it is to be understood that some embodiments are not limited to the disclosed embodiments. The scope of the following claims is to be accorded the broadest interpretation so as to encompass all such modifications and equivalent structures and functions.

This application claims priority to Japanese Patent Application No. 2025-012292, which was filed on Jan. 28, 2025 and which is hereby incorporated by reference herein in its entirety.

What is claimed is:

1. A stage apparatus comprising:
a substrate chuck configured to support a substrate;
a supplier configured to supply a gas to a space between the substrate and the substrate chuck;
a pin member configured to support the substrate by protruding from a hole formed in the substrate chuck;
a driver configured to relatively move the substrate chuck and the pin member;
a detector configured to detect a gap between an end portion of the substrate and the substrate chuck; and
a controller configured to control gas supply by the supplier based on a result of detection by the detector in an operation of separating the substrate and the substrate chuck by the driver.

2. The apparatus according to claim 1, wherein
in the operation, the controller controls the supplier so as to supply a gas to the space in accordance with the detector detecting a presence of the gap.

3. The apparatus according to claim 2, wherein
during gas supply performed in accordance with the detector detecting a presence of the gap, the controller changes a gas supply amount in accordance with a progress of the operation.

4. The apparatus according to claim 3, wherein
the controller changes the gas supply amount based on at least one of a relative moving speed between the substrate chuck and the pin member, a size of the gap, a pressure of the space, a driving force of the driver, a drive current value in the driver, a load applied on the pin member, a deformation amount of the substrate, a strength of the substrate, and a material of the substrate.

5. The apparatus according to claim 4, wherein
the controller decides a timing of stopping gas supply based on at least one of a moving speed of the driver, the size of the gap, the pressure of the space, the driving force of the driver, the drive current value in the driver, the load applied on the pin member, the deformation amount of the substrate, the strength of the substrate, and the material of the substrate.

6. The apparatus according to claim 1, wherein
the detector detects the gap based on at least one of a pressure of the space, a relative position between the substrate and the substrate chuck, a height position of an end portion of the substrate, a control deviation by the driver, a moving speed of the driver, an acceleration of the driver, a driving force of the driver, a drive current value in the driver, a load applied on the pin member, a deformation amount of the substrate, and a deformation amount of the substrate chuck.

7. The apparatus according to claim 1, wherein the controller stops gas supply by the supplier before stopping the operation.

8. The apparatus according to claim 1, further comprising an open mechanism configured to open the space to the atmosphere,
wherein the controller further controls opening and closing of the open mechanism in the operation.

9. The apparatus according to claim 8, wherein
the controller opens the open mechanism after starting gas supply by the supplier.

10. The apparatus according to claim 8, wherein
the controller matches open and close timings of the open mechanism with start and end timings of gas supply by the supplier, respectively.

11. The apparatus according to claim 8, wherein the controller
controls the driver so as to set a relative moving speed between the substrate chuck and the pin member to a first speed and then to set the relative moving speed to a second speed higher than the first speed, after the substrate and the pin member contact in the operation, and
stops gas supply by the supplier and closes the open mechanism in a middle of a section where the second speed is set, after the substrate and the pin member contact in the operation.

12. A substrate processing apparatus comprising
a stage apparatus defined in claim 1,
wherein the substrate held by the stage apparatus is processed.

13. The apparatus according to claim 12, wherein
the apparatus is a lithography apparatus configured to form a pattern on th substrate.

14. An article manufacturing method comprising:
forming a pattern on a substrate using a substrate processing apparatus defined in claim 13; and
processing the substrate on which the pattern is formed in the forming,
wherein an article is manufactured from the processed substrate.

15. A control method of a stage apparatus including a substrate chuck configured to support a substrate, a supplier configured to supply a gas to a space between the substrate and the substrate chuck, a pin member configured to support the substrate by protruding from a hole formed in the substrate chuck, and a driver configured to move at least one of the substrate chuck and the pin member, the method comprising:
detecting a gap between an end portion of the substrate and the substrate chuck in an operation of separating the substrate and the substrate chuck by the driver; and
controlling gas supply by the supplier based on a result of the detecting.
